(19) United States
(12) Patent Application Publication
(10) Pub. No.: US 2025/0069887 A1
(43) Pub. Date: Feb. 27, 2025

(54) CALIBRATING TUNING PARAMETERS FOR LASER TUNING JOSEPHSON JUNCTIONS

(71) Applicant: International Business Machines Corporation, Armonk, NY (US)

(72) Inventors: Eric Zhang, Sleepy Hollow, NY (US); Jason S. Orcutt, Katonah, NY (US); Jared Barney Hertzberg, Yorktown Heights, NY (US); Sami Rosenblatt, White Plains, NY (US); Yves Martin, Ossining, NY (US)

(21) Appl. No.: 18/452,963

(22) Filed: Aug. 21, 2023

(51) Int. Cl. H01L 21/02; G06N 10/40; H10N 60/01; H10N 60/12

(52) U.S. Cl. CPC H01L 21/02686; G06N 10/40; H01L 21/02678; H10N 60/0912; H10N 60/12

(57) ABSTRACT

A method for performing a calibration process comprises performing laser annealing operations on a set of test superconducting tunnel junction devices using different combinations of laser power and anneal time, determining junction resistance shifts of the test superconducting tunnel junction devices as a result of the laser annealing operations, and utilizing the determined junction resistance shifts of the test superconducting tunnel junction to determine calibration data for configuring laser annealing operations for laser tuning superconducting tunnel junction devices corresponding to the test superconducting tunnel junction devices.

### BACKGROUND

This disclosure relates generally to techniques for tuning Josephson junction devices and, in particular, the laser annealing techniques for tuning tunnel junction resistances of Josephson junction devices. A quantum computing system can be implemented using superconducting circuit quantum electrodynamics (cQED) architectures that are constructed using quantum circuit components such as, e.g., superconducting quantum bits (e.g., fixed-frequency transmon quantum bits), superconducting quantum interference devices (SQUIDs), and other types of superconducting devices which comprise Josephson junction devices. In particular, superconducting quantum bits (qubits) are electronic circuits which are implemented using components such as superconducting tunnel junctions (e.g., Josephson junctions), inductors, and/or capacitors, etc., and which behave as quantum mechanical anharmonic (non-linear) oscillators with quantized states, when cooled to cryogenic temperatures. A fixed-frequency qubit, such as a transmon qubit, has a transition frequency (denoted for) which corresponds to an energy difference between a ground state |0 [symbol] and a first excited state |1 [symbol] of the qubit. It is known that the transition frequency f₀₁ of a qubit can be estimated from the tunnel junction resistance (denoted R_{J}) of the Josephson junction of the qubit.

A solid-state quantum processor can include multiple superconducting qubits that are arranged in a given lattice structure (e.g., square lattice, heavy hexagonal lattice) to enable quantum information processing through quantum gate operations (e.g., single-qubit gate operations and multi-qubit gate operations) in which quantum information is generated and encoded in computational basis states (e.g., |0 [symbol] and |1 [symbol] ) of single qubits, superpositions of the computational basis states of single qubits, and/or entangled states of multiple qubits. Continuing technological advances in quantum processor design are enabling the rapid scaling of both the physical number of superconducting qubits and the computational capabilities of quantum processors. Indeed, while current state-of-the art quantum processors have greater than 50 qubits, it is anticipated that future quantum processors will have a much larger number of qubits, e.g., on the order of hundreds or thousands of qubits, or more.

Scaling the number of qubits (e.g., fixed frequency transmon qubits) in a qubit lattice, while maintaining high-fidelity quantum gate operations, remains a key challenge for quantum computing. For example, as superconducting quantum processors scale to larger numbers of qubits, frequency crowding within a qubit lattice becomes increasingly problematic since the transition frequencies of the qubits need to be precisely controlled to minimize gate errors that can arise from lattice frequency collisions (e.g., improper detuning between superconducting qubits can reduce the fidelity of multi-qubit gate entanglement operations). Due to semiconductor processing variabilities, however, the transition frequencies of superconducting qubits as fabricated can deviate from design targets.

In this regard, laser annealing techniques can be used to adjust qubit frequencies post-fabrication and thereby selectively tune fixed-frequency qubits of a given qubit lattice into desired frequency patterns. In particular, laser annealing techniques can be utilized to increase collision-free yield of fixed-frequency qubit lattices by selectively trimming (i.e., tuning) individual qubit frequencies, post-fabrication, by enabling localized thermal annealing the Josephson junctions of the qubits to thereby adjust and stabilize the tunnel junction resistance R_{J} of the respective Josephson junctions (and correspondingly, the respective qubit transition frequencies f₀₁) with high precision. The tuning of qubit transition frequencies through laser thermal annealing, however, is non-trivial due to, e.g., inherent variabilities of the laser thermal anneal process itself and/or the equipment that is utilized to perform such laser thermal annealing, post fabrication, to tune the qubit transition frequencies in a given qubit lattice.

### SUMMARY

Exemplary embodiments of the disclosure include techniques for generating tuning calibration data for configuring laser annealing operations for laser tuning junction resistances of superconducting tunnel junction devices (e.g., Josephson junctions).

An exemplary embodiment includes a method for performing a calibration process. The calibration process comprises performing laser annealing operations on a set of test superconducting tunnel junction devices using different combinations of laser power and anneal time, determining junction resistance shifts of the test superconducting tunnel junction devices as a result of the laser annealing operations, and utilizing the determined junction resistance shifts of the test superconducting tunnel junction to determine calibration data for configuring laser annealing operations for laser tuning superconducting tunnel junction devices corresponding to the test superconducting tunnel junction devices.

Advantageously, the calibration process generates tuning calibration data which is representative of laser tuning characteristics of superconducting tunnel junction devices (e.g., Josephson junctions of quantum bit devices), wherein the calibration data can be used to configure laser tuning operations (e.g., selecting target combinations of laser power and laser anneal times, etc.) for laser tuning corresponding superconducting tunnel junction devices to respective target junction resistances while mitigating a risk of undershooting or overshooting the resistance tuning.

Another exemplary embodiment includes a method which comprises performing a laser annealing process to tune a plurality of superconducting tunnel junction devices on a quantum chip, wherein performing the laser annealing process comprises configuring a laser annealing process to laser tune a given superconducting tunnel junction device using tuning calibration data obtained by laser annealing operations performed on a set of test superconducting tunnel junction devices using different combinations of laser power and anneal time, the test superconducting tunnel junction devices corresponding to the given superconducting tunnel junction device.

Another exemplary embodiment includes a system which comprises a laser annealing apparatus, and a control system operatively coupled to the laser annealing apparatus. The laser annealing apparatus is controlled by the control system to perform a calibration process, wherein the control process is configured to: perform laser annealing operations on a set of test superconducting tunnel junction devices on a quantum chip, using different combinations of laser power and anneal time; determine junction resistance shifts of the test superconducting tunnel junction devices as a result of the laser annealing operations; and utilize the determined junction resistance shifts of the test superconducting tunnel junction to determine calibration data for configuring laser annealing operations for laser tuning superconducting tunnel junction devices corresponding to the test superconducting tunnel junction devices.

Another exemplary embodiment includes a system which comprises a laser annealing apparatus, and a control system operatively coupled to the laser annealing apparatus. The laser annealing apparatus is controlled by the control system to perform a laser tuning process wherein the control system is configured to perform a laser annealing operations to tune a plurality of superconducting tunnel junction devices on a quantum chip, wherein in performing the laser annealing operations, the control system configures a laser annealing operation to laser tune a given superconducting tunnel junction device using tuning calibration data obtained by laser annealing operations performed on a set of test superconducting tunnel junction devices using different combinations of laser power and anneal time, the test superconducting tunnel junction devices corresponding to the given superconducting tunnel junction device.

Another exemplary embodiment includes a computer program product for performing laser annealing. The computer program product comprises one or more computer readable storage media, and program instructions collectively stored on the one or more computer readable storage media. The program instructions comprises: program instructions to perform laser annealing operations on a set of test superconducting tunnel junction devices using different combinations of laser power and anneal time; program instruction to determine junction resistance shifts of the test superconducting tunnel junction devices as a result of the laser annealing operations; and program instructions to utilize the determined junction resistance shifts of the test superconducting tunnel junction to determine calibration data for configuring laser annealing operations for laser tuning superconducting tunnel junction devices corresponding to the test superconducting tunnel junction devices.

In another exemplary embodiment, as may be combined with the preceding paragraphs, the determined junction resistance shifts are utilized to determine a maximum tuning range for different combinations of laser power and anneal time.

In another exemplary embodiment, as may be combined with the preceding paragraphs, the determined junction resistance shifts are utilized to generate tuning curves that represent tuning rates for the different combinations of laser power and anneal time.

In other exemplary embodiments, as may be combined with the preceding paragraphs, each tuning curve corresponds to at least one of: a different laser power setting, wherein each calibration tuning curve provides information regarding a percentage of junction resistance shift as a function of anneal time for the different laser power settings; and a different percentage of junction resistance shift, wherein each calibration tuning curve provides information regarding anneal time as a function of laser power for the different percentages of junction resistance shift.

In another exemplary embodiment, as may be combined with the preceding paragraphs, wherein the set of test superconducting tunnel junction devices reside on a test quantum chip having the test superconducting tunnel junction devices which are fabricated using fabrication processes which are the same fabrication processes used to fabricate a plurality of superconducting tunnel junction devices that are to be laser tuned by laser annealing operations configured using the calibration data.

In another exemplary embodiment, as may be combined with the preceding paragraphs, wherein the set of test superconducting tunnel junction devices reside on a quantum chip having the test superconducting tunnel junction devices and a plurality of superconducting tunnel junction devices that are to be laser tuned by laser annealing operations configured using the calibration data.

Other embodiments will be described in the following detailed description of exemplary embodiments, which is to be read in conjunction with the accompanying figures.

### BRIEF DESCRIPTION OF THE DRAWINGS

FIG. 1 schematically illustrates a laser annealing system for tuning Josephson junctions, according to an exemplary embodiment of the disclosure.

FIG. 2 illustrates a flow diagram of a calibration process for obtaining calibration data for use in laser tuning Josephson junctions, according to an exemplary embodiment of the disclosure.

FIG. 3 illustrates a graph of calibration curves which represent calibration data obtained for different combinations of laser power and anneal time, according to an exemplary embodiment of the disclosure.

FIGS. 4A and 4B illustrate a flow diagram of a calibration process for obtaining calibration data for use in laser tuning Josephson junctions, according to another exemplary embodiment of the disclosure.

FIG. 5 depicts a graph which illustrates tuning curves that are determined using tuning range data obtained from laser annealing calibration tests, according to an exemplary embodiment of the disclosure.

FIG. 6A illustrates process for utilizing tuning calibration data of Josephson junctions to calibrate a process for tuning transition frequencies of superconducting qubits, according to an exemplary embodiment of the disclosure.

FIG. 6B illustrates a flow diagram of a method for generating a frequency tuning plan, according to an exemplary embodiment of the disclosure.

FIG. 6C illustrates a flow diagram of a method for utilizing laser tuning calibration data to determine laser annealing parameters for performing initial laser tuning operations on Josephson junctions, according to an exemplary embodiment of the disclosure.

FIG. 6D illustrates a process of using tuning calibration data to determine a given power level setting to assign to a given Josephson junction based on a selected anneal time and initial laser anneal operation, according to an exemplary embodiment of the disclosure.

FIG. 7 depicts a graph which illustrates tuning curves that are determined using tuning range data obtained from laser annealing calibration tests, according to another exemplary embodiment of the disclosure.

FIG. 8 illustrates a flow diagram of a method for tuning Josephson junctions, according to an exemplary embodiment of the disclosure.

FIG. 9 schematically illustrates a process for aligning contact probes and laser spots to a Josephson junction of a quantum bit, according to an exemplary embodiment of the disclosure.

FIG. 10 schematically illustrates an exemplary architecture of a computing environment for implementing a control system that is configured to control a laser annealing system for tuning Josephson junctions, according to an exemplary embodiment of the disclosure.

### DETAILED DESCRIPTION

Exemplary embodiments of the disclosure will now be described in further detail with regard to techniques for generating tuning calibration data (e.g., calibration tuning parameters) for configuring laser annealing operations for laser tuning superconducting tunnel junction devices, e.g., laser tuning Josephson junctions of superconducting qubits, as well as techniques for utilizing the calibration data to generate frequency tuning plans for frequency collision avoidance in multi-qubit lattices of a given topology (e.g., a heavy-hexagonal lattice, a square lattice, and the like) and performing LASIQ tuning operations to tune the transition frequencies of superconducting qubits by laser tuning junction resistances of the qubit Josephson junctions using the exemplary calibration and laser tuning techniques as discussed herein.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs. In addition, the terms “about” or “substantially” as used herein with regard to, e.g., percentages, ranges, etc., are meant to denote being close or approximate to, but not exactly. For example, the term “about” or “substantially” as used herein implies that a small margin of error may be present, such as 1% or less than the stated amount.

It is to be further understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

Further, the term “quantum chip” as used herein is meant to broadly refer to any device which comprises qubits and possibly other quantum devices. For example, a quantum chip can be semiconductor die which comprises an array (lattice) of qubits, which is fabricated on a wafer comprising multiple dies, and which can be diced (cut) from the wafer using a die singulation process to provide a singulated die. In some instance, a quantum chip can be a wafer with multiple semiconductor die. In the context of quantum computing, a quantum chip may comprise one or more processors for a quantum computer.

Moreover, the term “shot” as used herein denotes a laser anneal operation that is performed by applying laser power to a target element (e.g., Josephson junction) for a specified duration (anneal time) to tune the target element. In the context of exemplary embodiments of the disclosure as discussed herein, laser tuning methods are provided to tune junction resistances of Josephson junctions in a progressive and incremental manner wherein multiple “shots” are applied to a given Josephson junction to tune the junction resistance of the Josephson junction to a target junction resistance, which is to be contrasted with conventional approaches that tune a Josephson junction to a target junction resistance using only one laser shot.

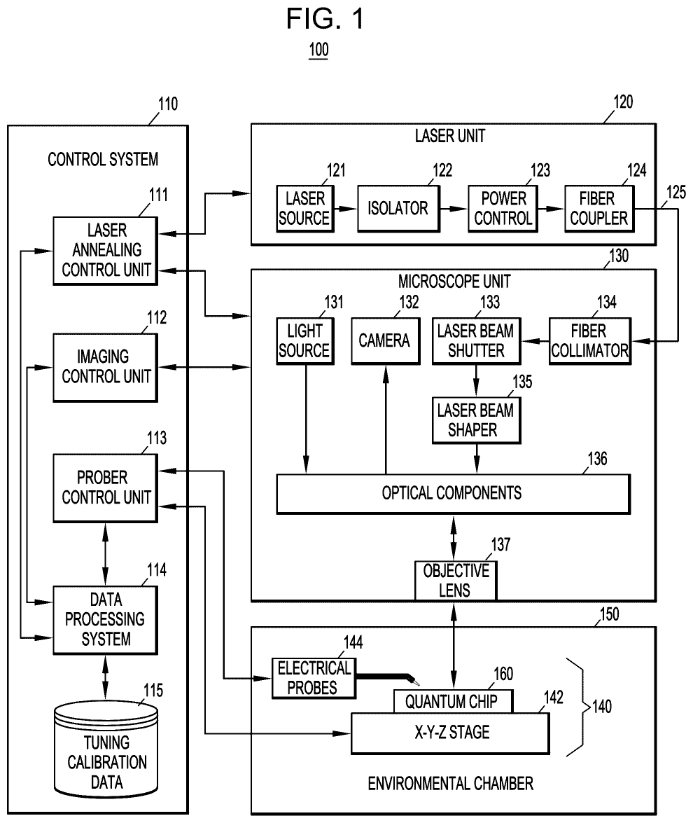

FIG. 1 schematically illustrates a laser annealing system 100 for tuning Josephson junctions, according to an exemplary embodiment of the disclosure. In some embodiments, the laser annealing system 100 is configured to implement LASIQ (Laser Annealing of Stochastically Impaired Qubits) tuning methods for laser annealing of Josephson junctions of qubits, post-fabrication, to adjust and stabilize the junction resistances Ry and thereby selectively tune the individual qubit frequencies via laser thermal annealing of the respective Josephson junctions. As schematically shown in FIG. 1, the laser annealing system 100 comprises a control system 110, a laser unit 120, an optical fiber 125, a microscope unit 130, a prober unit 140, and optional environmental chamber 150.

The control system 110 comprises a laser annealing control unit 111, an imaging control unit 112, a prober control unit 113, a data processing system 114, and a database of tuning calibration data 115. The laser unit 120 comprises a laser source 121, an isolator 122, a laser power control block 123, and a fiber coupler 124. The microscope unit 130 comprises a light source 131, a camera 132, a laser beam shutter 133, a fiber collimator 134, a laser beam shaper 135, a plurality of optical components 136, and an objective lens 137. The prober unit 140 comprises an X-Y-Z stage 142, and electrical probes 144. A quantum chip 160 (or any other similar device under test) can be mounted to the X-Y-Z stage. In some embodiments, the quantum chip comprises a lattice of superconducting qubits, where each superconducting qubit comprises at least one respective Josephson junction which can be annealed using the laser annealing system 100 to tune the junction resistance and, thus, tune the transition frequency of the superconducting qubit, post-fabrication.

In some embodiments, the laser unit 120 and the microscope unit 130 comprise modular units that are coupled together via the optical fiber 125. In some embodiments, the optical fiber 125 comprises a single-mode (SM) polarization-maintaining (PM) optical fiber, which is configured to preserve a linear polarization of linearly polarized light that is injected into the optical fiber 125 by the laser unit 120 and propagated to the microscope unit 130. The microscope unit 130 comprises a modular optical unit which comprises visible light and laser optical components. The microscope unit 130 can be integrated onto the prober unit 140 (e.g., a wafer-scale prober). In this regard, in some embodiments, the laser unit 120, the microscope unit 130, and the prober unit 140 can be physically coupled/attached to each other to form an integrated laser annealing apparatus which is configured to perform laser anneal operations for tuning junction resistances of Josephson junctions, as well as performing in-situ junction resistance measurements, under the control of the control system 110. In some embodiments, the control system 110 is operatively/communicatively coupled to the laser unit 120, the microscope unit 130, and the prober unit 140 via wires and/or wirelessly. The control system 110 comprises hardware and/or software for automated control of various operations of the laser unit 120, the microscope unit 130, and the prober unit 140 of the laser annealing system 100.

The laser unit 120 is configured to generate a laser beam that is used by the microscope unit 130 to generate a laser beam pattern which comprises a single or multi-spot beam pattern for laser annealing a given Josephson junction. In some embodiments, the laser source 121 comprises a solid-state diode pump to generate laser energy, and a laser head to generate a focused laser beam from the laser energy emitted from the solid-state diode pump. In some embodiments, the diode pump comprises a 532 nanometer (nm) (frequency doubled) diode-pumped solid-state laser (e.g., a second harmonic generation (SHG) laser). In some embodiments, the power level of the laser source 121 (e.g., solid-state diode pump) can be adjusted by the control system 110. For example, the power level of the laser source 121 can be set to one of a plurality of different power level settings (e.g., lower power, medium power, high power settings). The isolator 122 is configured to provide polarization cleanup and optical isolation to mitigate unwanted feedback to the laser head of the laser source 121.

The laser power control block 123 is configured to actively control and calibrate the power of the focused laser beam. For example, in some embodiments, the laser power control block 123 comprises a half-wave plate, and a polarizing beam-splitter (PBS) coupled to a dump. Th half-wave plate is configured to shift the polarization direction of the laser beam output from the isolator 122. The laser power control block 123 further comprises a power monitor which comprises, e.g., an optical wedge that is configured to divert some laser beam power to a silicon photodiode. The silicon photodiode generates an electrical signal that is indicative of the laser power level, and the electrical signal is feedback to the control system 110 (e.g., the laser annealing control unit 111), the control system 110 generates control signals that are applied to the laser power control block 123 to adjustably control the laser power, as directed, for laser tuning of Josephson junctions. More specifically, in some embodiments, the power level of the laser beam can be coarsely adjusted by controlling the power output of the laser source 121, while the power level of the laser beam can be finely adjusted by operation of the laser power control block 123.

For example, in some embodiments, the half-wave plate of the laser power control block 123 is configured to shift the polarization direction of the laser beam output from the isolator 122, and the half-wave plate comprises an adjustable rotation, which can be electronically-controlled via the laser annealing control unit 111 to adjust a total attenuation by rotating the polarization incident on the polarizing beam splitter to the desired power level. In some embodiments, the polarizing beam splitter of the laser power control block 123 comprises an optical filter that allows a specific polarization of light waves associated with the laser beam to pass through the optical filter and blocks light waves of other polarizations, to thereby generate a laser beam with well-defined polarized light.

The polarized laser light generated by the laser unit 120 is coupled into the single-mode polarizing-maintaining optical fiber 125 (e.g., single-mode polarizing-maintaining optical fiber) via the optical fiber coupler 124, and propagates to the microscope unit 130. In the microscope unit 130, the fiber collimator 134 (e.g., collimating lens) is configured to transform the laser light which is output from the optical fiber 125 into a free-space collimated beam. In some embodiments, the microscope unit 130 comprises a power monitor which comprises, e.g., a beam sampler (e.g., beam splitter) and photodiode, to monitor the power of the collimated laser beam to enable precise exposure control downstream from the power control/adjustment mechanisms provided by the laser unit 120.

Furthermore, in the microscope unit 130, the laser beam shutter 133 comprises an electronic shutter that is operated under control of, e.g., the laser annealing control unit 111 of the control system 110, to control the time duration of laser exposure when annealing a given Josephson junction. For example, the laser beam shutter 133 can be opened for a given duration of time when annealing a target Josephson junction to allow annealing laser beams to be projected onto the quantum chip 160 in proximity to the target Josephson junction, and then automatically close after the given duration of time. In this regard, the laser power level and the pulse duration (laser exposure) can be controlled to achieve a desired change (e.g., decrease) in the resistance of the annealed Josephson junction.

The laser beam shaper 135 is configured to split the collimated laser beam (which passes through the laser beam shutter 133) into two or more laser beams with slightly different angles relative to one another. In some embodiments, the laser beam shaper 135 comprises a diffractive optical element (DOE), such as a diffractive beam splitter which splits a single laser beam into several beams (diffraction orders) in a predefined configuration. The diffractive beam splitter comprises a holographic optical element that imparts a precise angle (e.g., a 0.5 degree shift) to the incoming laser beam in plus and minus angular directions relative to a reference plane, to thereby generate a plurality of outgoing laser beams.

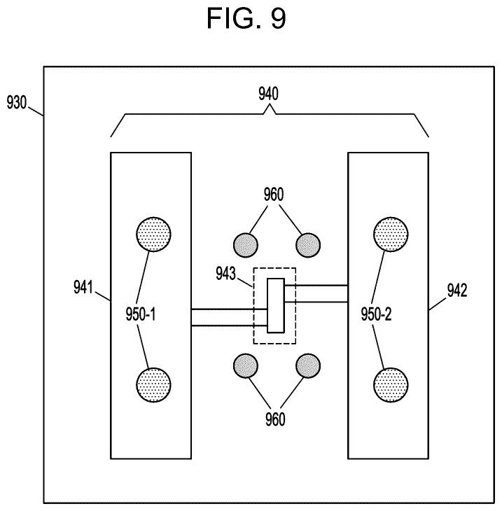

The number of laser beams generated by the laser beam shaper 135 can vary depending on the given application. For example, in some embodiments, laser beam shaper 135 comprises a 2-by-2 diffractive beam splitter, which splits the single collimated laser beam into four separate laser beams, which results in a final quad-spot illumination pattern that is projected onto the surface of the quantum chip 160 at a target location, an exemplary embodiment of which will be discussed below in conjunction with FIG. 9. In some embodiments, the laser beam shaper 135 can be switched either manually or automatically with a different diffractive beam splitter (e.g., a plurality of DOEs on a rotary stage) to obtain a different laser spot pattern, as desired. In this regard, different diffractive beam splitters can be selected for use to generate any desired number (e.g., 2, 3, 5, 6, etc.) of laser beams with defined illumination patterns tailored to different applications.

The microscope unit 130 implements the light source 131 and the camera 132 for illuminating and viewing target features (e.g., qubits and corresponding Josephson junctions) on the surface of the quantum chip 160 within a given field of view (FOV) of the microscope unit 130. In some embodiments, the light source 131 comprises any suitable light generating device including one or more light emitting diodes (LEDs) with desired photonic wavelengths, a monochromatic light source, etc. The light source 131 together with some of the optical components 136 in the optical viewing path implement Kohler illumination to create uniform illumination of the target features in the FOV of the microscope unit 130 and to ensure that an image of the light source 131 is not visible in the resulting images captured by the camera 132.

In some embodiments, the camera 132 comprises a charge-coupled device (CCD) image sensor, or an infrared (IR) complementary metal oxide semiconductor (CMOS) image sensor. The camera 132 is utilized to capture images of a target region on the surface of the quantum chip 160 to facilitate, e.g., aligning the electrical probes 144 to contact electrodes when performing in-situ Josephson junction resistance measurements, aligning the laser beam pattern onto the target region when performing laser annealing operations, etc. For example, in some embodiments, the Josephson junction of a given qubit is aligned to the center of the FOV of the microscope unit 130 using pattern recognition to, e.g., a Josephson junction template image.

The optical components 136 include various types of optical components for directing, reflecting, focusing, modifying, and shaping, etc., the optical signals (e.g., laser beams for annealing, and visible light/IR light for viewing) as needed for the given application. For example, the optical components 136 include components such as a mirror, beam splitters, filters, polarizers, and various lenses such as a tube lens, an objective lens, relay lenses, etc.). The objective lens 137 is the lens that is located closest to the device under test (quantum chip 160) and serves to provide the base magnification for generating a magnified image that is viewed by the camera 132, and to project the annealing laser beam pattern (e.g., quad-spot pattern) onto the surface of the quantum chip 160. In some embodiments, the objective lens 137 comprises a long working distance (WD) objective lens. In an exemplary non-limiting embodiment, the objective lens 137 (together with an optional second objective lens) is configured to condense the laser beams and multi-spot pattern by 4×, while providing 20× image magnification.

The prober unit 140 is configured to automatically move the position of the quantum chip 160 during a laser annealing process to align a target Josephson junction of a given qubit within the FOV of the microscope unit 130 to perform an in-situ Josephson junction resistance measurement and a laser anneal of the target Josephson junction. In particular, the quantum chip 160 is mounted to the automated X-Y-Z stage 142 which is controllably moved in three dimensions to align features of the quantum chip 160 within the FOV of the microscope unit 130 and enable contact between the electrical probes 144 and contact pads on the quantum chip 160. For example, in some embodiments, during a laser anneal process, a target Josephson junction of a given qubit is aligned to the center of the FOV of the microscope unit 130 using an automated pattern recognition process in which features of an image captured by the camera 132 are automatically aligned to corresponding features of a template image to ensure proper positioning of the target Josephson junction and associated contact pads. In particular, an alignment process is performed to ensure accurate registration between the contact pads of the target Josephson junction and the electrical probes 144 when performing an in-situ Josephson junction resistance measurement. In addition, an alignment process is performed to ensure a proper alignment of the target Josephson junction and a laser spot pattern when performing a laser anneal operation.

As noted above, the electrical probes 144 are implemented to perform in-situ Josephson junction resistance measurements during a laser anneal process. In particular, in-situ Josephson junction resistance measurements are performed in between laser annealing operations (shots) to track the tuning progress of the Josephson junctions of the qubits during a multi-step anneal process in which the Josephson junctions are progressively tuned. In some embodiments, the electrical probes 144 comprise two pairs of probes, which are configured to perform a 4-wire resistance measurement (or Kelvin resistance measurement) to more precisely measure the junction resistance of a Josephson junction. In general, a 4-wire (Kelvin) resistance measurement involves determining the resistance of a given Josephson junction by measuring a current (I) flow through the junction as well as a voltage (V) drop across the junction, and determining the junction resistance R_{J} from Ohm's Law, i.e., R_{J}=V/I.

In some embodiments, the electrical probes 144 comprise a probe card that is mechanically mounted in a fixed position to the prober unit 140. In some embodiments, the integration of the microscope unit 130 and the prober unit 140 is configured to ensure that a sample imaging plane and a laser focal plane are substantially identical, while a probing plane is displaced from the sample imaging plane by a present amount, e.g., 70 microns, 80 microns, etc. In this configuration, the electrical probes 144 are fixedly displaced from the image plane, and the Z-position of the X-Y-Z stage 142 (with the quantum chip 160 mounted thereon) is moved into a default contact position to make electrical contact between the electrical probes 144 and target contact pads on the quantum chip 160, to perform an in-situ Josephson junction resistance measurement.

In some embodiments, the prober unit 140 is housed or otherwise disposed within the optional environmental chamber 150 to control an ambient environment during laser annealing, wherein different ambient environments impact the laser annealing progression differently. For example, in some embodiments, the laser annealing system 100 may comprise an environmental gas control system which is coupled to the environmental chamber 150 and which is configured to inject a mixture of one or more gases into the environmental chamber 150 to control the annealing environment. More specifically, in some embodiments, the environmental gas control system may comprise a gas dilution unit which is connected to a plurality of gas cylinders which store different gases (e.g., nitrogen, dry air, etc.), wherein the gas dilution unit can mix different gases at various concentrations and inject the mixed gases into the environmental chamber 150, as desired, to provide a given gas environment for laser annealing. In addition, the environmental gas control system comprises a vacuum system coupled to the environmental chamber 150 to evacuate anneal gases from the chamber or otherwise evacuate air from the environmental chamber 150 to perform laser annealing in a vacuum atmosphere.

Moreover, in some embodiments, a temperature control system is coupled to the X-Y-Z stage 142 (e.g., wafer chuck) to control the temperature of the X-Y-Z stage 142 on which the quantum chip 160 is mounted. The X-Y-Z stage 142 may be temperature controlled to allow high-temperature anneals (e.g., bulk anneals) or low-temperature probing for low-noise electrical resistance measurements. For example, in some embodiments, the X-Y-Z stage 142 can be temperature controlled in a range of −60° C. to 300° C.

As noted above, various functions of the laser unit 120, the microscope unit 130, and the prober unit 140 are automatically controlled by the control system 110. In some embodiments, the laser annealing control unit 111, the imaging control unit 112, and the prober control unit 113, comprise respective hardware interfaces for interfacing with the laser unit 120, the microscope unit 130, and the prober unit 140, as needed, to generate and apply control signals to components of such units 120, 130, and 140, and to receive and process signals (e.g., data, measurements, feedback controls signals, etc.) received from components of such units 120, 130, and 140. The data processing system 114 comprises one or more processors that execute software programs/routines to control laser annealing, imaging, and prober operations by processing data received from the control units 111, 112, and 113 (e.g., to perform automated pattern recognition for active alignments, perform junction resistance measurement computations, etc.), and generating and outputting control signals to cause the control units 111, 112, and 113, to control the operations of the laser unit 120, the microscope unit 130, and the prober unit 140 in a coordinated manner, when performing laser annealing and in-situ junction resistance measurements, as discussed herein.

For example, in some embodiments, the laser annealing control unit 111 is configured to control operation of components of the laser unit 120, such as the laser source 121 and the laser power control block 123, to adjust the power level of the laser beam output from the laser unit 120. In addition, the laser annealing control unit 111 is configured to control the operation of the components of the microscope unit 130 for laser annealing operations. For example, the laser annealing control unit 111 is configured to control the operation of the laser beam shutter 133 to control the duration of laser exposure when laser tuning a given Josephson junction. Further, in some embodiments, the laser annealing control unit 111 is configured to control the laser beam shaper 135, e.g., to switch the diffractive beam splitter settings and corresponding laser illumination patterns.

Further, in some embodiments, the imaging control unit 112 is configured to control the operation of the light source 131, the camera 132, and one or more of the optical components 136 (e.g., tube lens) that make up the image path of the microscope unit 130. For example, the imaging control unit 112 can generate camera control signals to cause the camera 132 to capture images within the FOV of the microscope unit 130 and send images to the imaging control unit 112. The imaging control unit 112 can be configured to preprocess the image data into a suitable format for processing by the data processing system 114 to perform automated pattern recognition functions to perform laser alignment and electrical probe alignment operations as discussed herein.

Moreover, in some embodiments, the prober control unit 113 is configured to control operations of the prober unit 140. For example, the prober control unit 113 comprises hardware for generating test voltages that are applied to the electrical probes for performing junction resistance measurements, e.g., for a 4-wire (Kelvin) resistance measurement, the prober control unit 113 may comprise current and voltage measurement circuitry, which is coupled to the electrical probes 144, and configured to measure current that flows through a Josephson junction as a result of applying a test voltage to the electrical probes, as well as measure a voltage across the Josephson junction. The measured currents and voltages can be digitized and sent to the data processing system 114 for computing junction resistances. In addition, the prober control unit 113 comprises control elements to precisely control movement and positioning of the X-Y-Z stage 142.

In some embodiments, the data processing system 114 executes a calibration process by performing laser annealing operations on Josephson junctions of representative hardware, using different combinations of laser anneal power and anneal time, to generate tuning calibration data (stored in the database of tuning calibration data 115). The tuning calibration data can be obtained by performing a calibration process on representative hardware which, in some embodiments, can be test (dummy) Josephson junctions that reside on the same quantum chip to be tuned, and in other embodiments, can be Josephson junctions of qubits that are formed on a sister chiplet from the same fabrication process. The tuning calibration data is analyzed using statistical methods to fit the tuning calibration data to tuning curves, wherein the tuning curves are utilized to determine tuning rates and maximum tuning ranges for Josephson junctions under different laser anneal powers and anneal times. The tuning curves are utilized by the data processing system 114 to select a target combination of anneal power and annal time, as desired, for a target tuning rate and maximum tuning range for laser annealing Josephson junctions of the given quantum chip, post fabrication. In some embodiments, the tuning curves are used to predict an initial laser anneal operation (initial shot) for tuning a given Josephson junction to a certain target (e.g., 50% to target) on a first shot. The calibration process ensures a smooth and rapid approach to a target tuning for a given Josephson junction, while mitigating risk of both undershooting and overshooting the tuning.

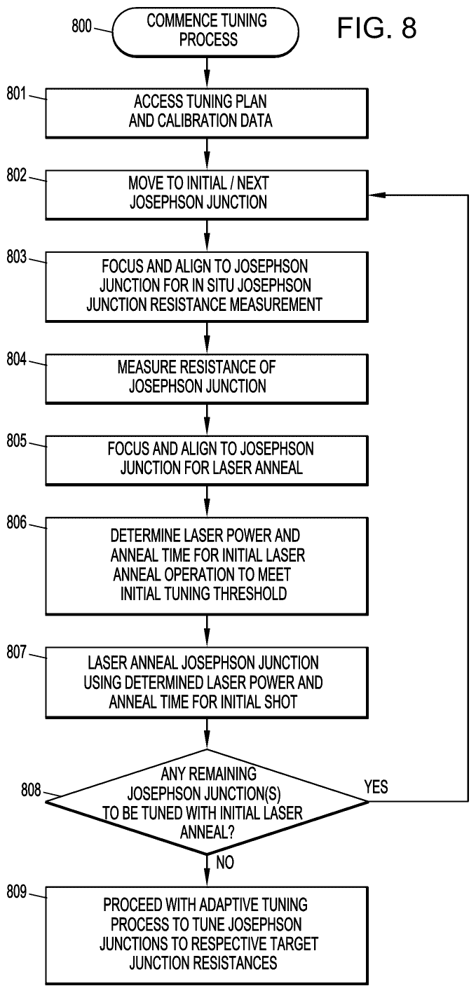

In some exemplary embodiments, the control system 110 for the laser annealing system 100 may be implemented using any suitable computing system architecture which is configured to implement methods to support the automated control processes as described herein by executing computer readable program instructions that are embodied on a computer program product which includes a computer readable storage medium (or media) having such computer readable program instructions thereon for causing a processor to perform control methods as discussed herein. An exemplary architecture of a computing environment for implementing a control system that is configured to control the laser annealing apparatus for tuning Josephson junctions, will be discussed in further detail below in conjunction with FIG. 8.

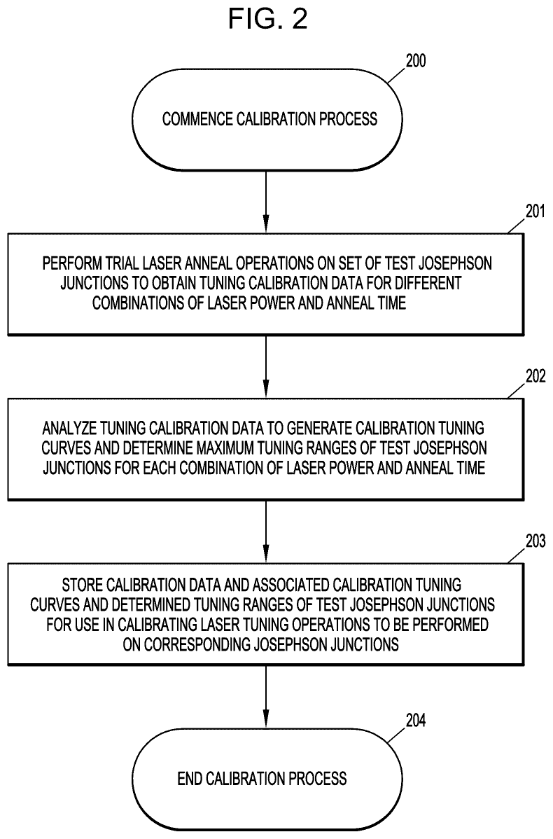

It is to be appreciated that the exemplary laser annealing system 100 of FIG. 1 can be utilized to perform exemplary calibration processes, such as discussed below in conjunction with FIGS. 2, 3, 4A, 4B 5, 6A, 6B, 6C, 6D, 7, 8, and 9, for generating calibration data (e.g., calibration tuning parameters) for laser tuning superconducting tunnel junction devices, e.g., laser tuning Josephson junctions of superconducting qubits, and other associated methods for generating and implementing tuning plans for frequency collision avoidance in multi-qubit lattices and performing LASIQ tuning operations to tune the transition frequencies of superconducting qubits by tuning junction resistances of the qubit Josephson junctions using the exemplary calibration and laser tuning techniques as discussed herein.

As noted above, the exemplary calibration techniques as discussed herein are configured to obtain tuning calibration data by performing trial laser anneal operations on representative hardware comprising Josephson junction (e.g., qubits with Josephson junctions), and utilize the tuning calibration data to determine various tuning metrics including, e.g., tuning rates and maximum tuning ranges for various combinations of laser power and anneal times, and utilize the tuning metrics for configuring tuning processes for laser tuning the Josephson junction on a quantum chip. For example, FIG. 2 illustrates a flow diagram of a calibration process for obtaining calibration data for use in tuning Josephson junctions, according to an exemplary embodiment of the disclosure. In some embodiments, FIG. 2 illustrates a calibration process that can be performed using the laser annealing system 100 of FIG. 1 with the control system 110 executing a calibration algorithm.

A quantum chip is placed on the X-Y-Z stage 142 of the prober unit 140, and the control system 110 commences an automated calibration process (block 200). The quantum chip comprises a set of test Josephson junctions which are representative of actual Josephson junctions that are to be laser tuned using the calibration data obtained from the calibration process. In some embodiments, the quantum chip is a test chip, e.g., a sister chiplet from a same wafer having quantum devices and Josephson junctions that were fabricated using the same fabrication processes (e.g., junction evaporation process) as the Josephson junctions on the actual quantum chip. In this regard, the Josephson junctions on the test chip (e.g., sister chiplet) are deemed to correspond to the Josephson junctions on the actual chip which are to be tuned by laser annealing operations that are configured using the calibration data obtained from the calibration operations performed on the test Josephson junctions on the test chip, since the test Josephson junctions and the actual Josephson junctions are fabricated using the same or similar processes. In this regard, the test Josephson junctions are assumed to have the same, or substantially the same, or similar laser tuning characteristics as the Josephson junctions on the actual chip which are to be tuned by laser annealing operations that are configured using the calibration data obtained from the calibration operations performed on the test Josephson junctions on the test chip.

In other embodiments, the calibration process may be implemented using a collection of test Josephson junction devices that reside on the same quantum chip which has the actual Josephson junctions that are to be tuned. For example, the collection of Josephson junctions can be a dedicated test array of Josephson junctions that are formed on the quantum chip and located, e.g., in the kerf of the quantum chip. In this regard, the collection of test Josephson junctions on the quantum chip correspond to the actual Josephson junctions on the same quantum chip, which are to be laser tuned by laser annealing operations that are configured using the calibration data obtained from the calibration operations performed on the test Josephson junctions on the same quantum chip. Since the collection of test Josephson junctions and the actual Josephson junctions (residing on the same quantum chip) are fabricated using the same fabrication processes, the test Josephson junctions and actual Josephson junction (to be laser tune) will have the same, or substantially the same, or similar tuning characteristics.

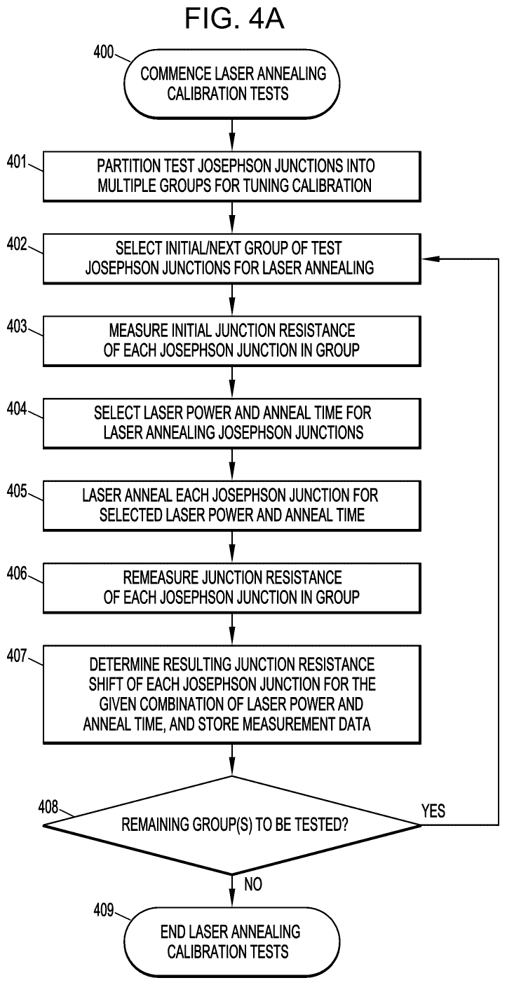

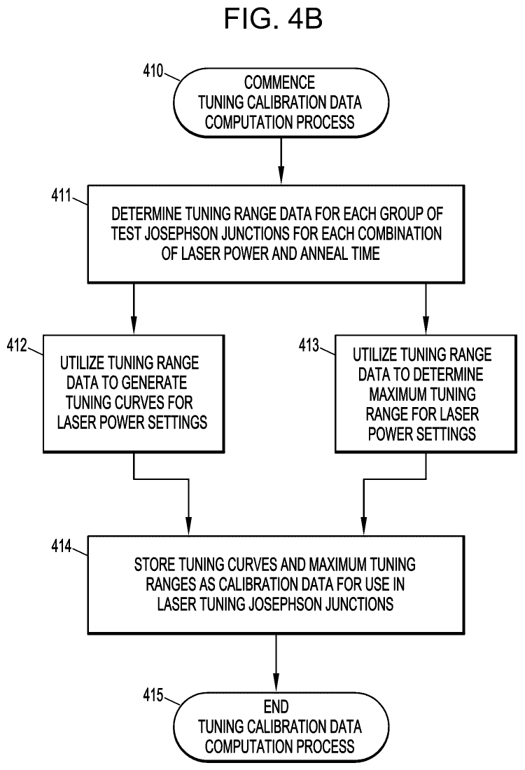

The calibration process proceeds by performing a series of trial laser anneal operations on a set of test Josephson junctions to obtain calibration data for different combinations of laser power and anneal time (block 201). For example, in some embodiments, the calibration process is performed by selecting a plurality of discrete laser power settings, e.g., 1.60 watts (W) (low power setting), 1.80 W (medium power), and 2.0 W (high power), and a plurality of anneal times for each laser power setting, e.g., a set of anneal times 0.5 s, 1.0 s, 2.0 s, 5.0 s, 10.0 s, 20.0 s, and 100 s for each of the discrete laser power settings (e.g., 1.60 watts at anneal times of 0.5 s, 1.0 s, 2.0 s, 5.0 s, 10.0 s, 20.0 s, and 100 s, etc.). For each laser power/anneal time combination, laser annealing operation are performed on respective groups of trial Josephson junctions (e.g., 3-10 Josephson junctions per group) to obtain a statistically significant amount of tuning calibration data. An exemplary calibration process for laser annealing the collection of test Josephson junctions to obtain tuning calibration data will be discussed in further detail below in conjunction with FIG. 4.

The calibration process analyzes the tuning calibration data to generate calibration tuning curves and to determine maximum tuning ranges for the test Josephson junctions, for each combination of laser power and anneal time (block 202). As explained in further detail below, the tuning curves for respective combinations of laser power/anneal time provide information regarding the tuning rates of the Josephson junctions (e.g., the slope of a tuning curve in a nominal tuning regime (positive resistance shift tuning), and the maximum tuning ranges for respective combinations of laser power/anneal time provide information regarding a maximum amount of increase in resistance shift (increase) from an initial junction resistance to a maximum junction resistance. The calibration data and parameters, including the tuning curves and maximum tuning ranges for each respective combination of laser power and anneal time, are persistently stored (block 203) and the calibration process terminates (block 204). The persistently stored calibration data (e.g., tuning curves and maximum tuning ranges) is subsequently utilized for calibrating laser tuning operations that are to be performed on Josephson junctions to tune the respective junction resistances to respective target junction resistances, using tuning processes discussed in further detail below.

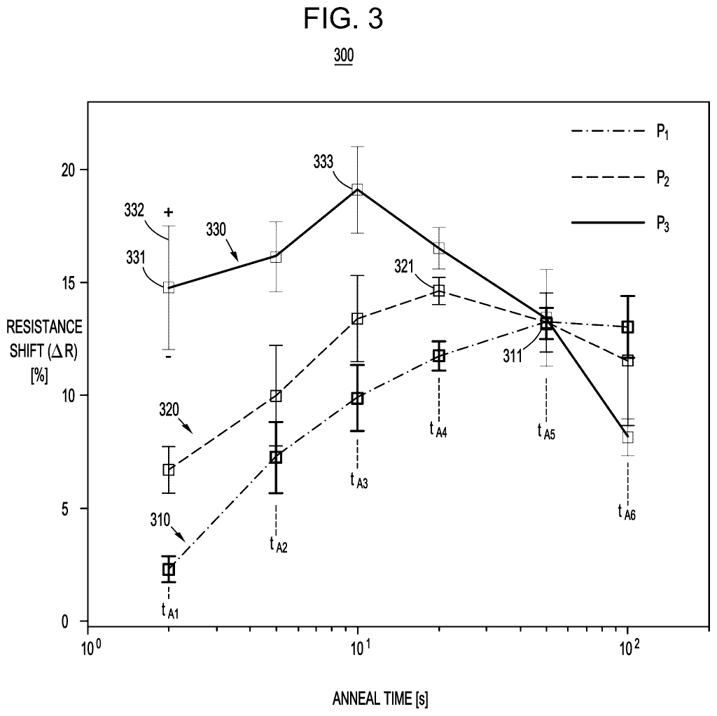

FIG. 3 illustrates a graph 300 of calibration curves which represent calibration data obtained for different combinations of laser power and anneal time, according to an exemplary embodiment of the disclosure. In particular, the graph 300 illustrates a plurality of calibration curves 310, 320, and 330 which represent an amount of junction resistance shift (ΔR) % as a function of anneal time t_{A} (e.g., discrete anneal times t_{A1}, t_{A2}, t_{A3}, t_{A4}, t_{A5}, and t_{A6}) for different laser power levels (e.g., P₁, P₂, and P₃). For example, the first calibration curve 310 (represented by a dashed-dotted line) illustrates an amount of junction resistance shift (ΔR) % obtained for groups of Josephson junctions laser annealed at a low laser power setting P₁ (e.g., 1.80 W) for respective anneal times t_{A1}, t_{A2}, t_{A3}, t_{A4}, t_{A5}, and t_{A6}. The second calibration curve 320 (represented by a dashed line) illustrates an amount of junction resistance shift (ΔR) % obtained for groups of Josephson junctions laser annealed at a medium laser power setting P₂ (e.g., 2.0 W) for respective anneal times t_{A1}, t_{A2}, t_{A3}, t_{A4}, t_{A5}, and t_{A6}, ranging from t_{A1}=2 s to t_{A6}=100 s. The third calibration curve 330 (represented by a solid line) illustrates an amount of junction resistance shift (ΔR) % obtained for groups of Josephson junctions laser annealed at a high laser power setting P₃ (e.g., 2.2 W) for respective anneal times t_{A1}, t_{A2}, t_{A3}, t_{A4}, t_{A5}, and t_{A6}.

It is to be noted that term ΔR denotes a difference between an initial junction resistance (denoted Rᵢₙᵢₜᵢₐₗ) of given Josephson junction before laser annealing, and a current junction resistance (denoted R_{current}) of the given Josephson junction after one calibration “shot” at a given combination of laser power and anneal time, i.e., ΔR=R_{current}−Rᵢₙᵢₜᵢₐₗ. In this regard, the Y-axis of the graph 300 represents a “resistance shift percentage” which is determined as

$$\frac{Δ R}{{R}_{i nitial}} \times 100 \% = \frac{{R}_{c urrent} - {R}_{i nitial}}{{R}_{initial}} \times 100 \% .$$

It is to be noted that the term “current junction resistance” as used herein and in conjunction with the notation R is meant to denote a junction resistance measured in the sense of occurring in or existing at a present time, or a most recently measured junction resistance.

Moreover, each point (represented by a square block) of the calibration curves 310, 320, and 330 corresponds to a given group of test Josephson junctions (e.g., 5 test Josephson junctions) and represents an average ΔR % obtained for the given group of test Josephson junctions at a given combination of laser power and anneal time. For example, a point 331 of the calibration curve 330 represents that given group of test Josephson junctions laser annealed at the laser power setting P₃ for anneal time of tai had an average junction resistance shift (ΔR) % of approximately 15%. In this regard, assuming that each point of the calibration curves 310, 320, and 330 correspond to a different group of 5 test Josephson junctions, the calibration data shown in FIG. 3 is obtained using 90 test Josephson junctions divided into 18 groups of 5 test Josephson junctions. As further shown in FIG. 3, each point of the calibration curves 310, 320, and 330 comprises a corresponding error bar (e.g., error bar 332 for point 331 of calibration curve 330) which represents an amount of variability of the ΔR % data obtain for the group of test Josephson junctions calibrated at the given combination of laser power and anneal time corresponding to the given point.

The calibration curves 310, 320, and 330 illustrate an exemplary tuning progression as a function of anneal time wherein at a given anneal time, progressively faster tuning (i.e., greater average junction resistance shift (ΔR) %) is achieved at higher laser power settings. Further, the calibration curves 310, 320, and 330 illustrate an exemplary maximum tuning range that is achieved at each of the given laser power levels P₁, P₂, and P₃. In particular, a point 333 of the calibration curve 330 represents a maximum tuning range of ˜19% that is achieved at the high laser power setting P₃ and anneal time t_{A3}. Further, a point 321 of the calibration curve 320 represents a maximum tuning range of ˜14% that is achieved at the medium laser power setting P₂ and anneal time t_{A4}. Moreover, a point 311 of the calibration curve 310 represents a maximum tuning range of ˜12% that is achieved at the low laser power setting P₁ and anneal time t_{A5}. These calibration tuning curves represent an exemplary tuning progression whereby the maximum tuning range may be dependent upon the anneal power used during the junction tuning process. In general, the tuning range and tuning rate behavior is dependent upon the exact material composition, conformation, fabrication processes, and the like, and is most practically determined through an empirical means such as the calibration method shown in FIG. 3.

The beginning portions of the calibration curves 310, 320, and 330, starting from the initial points (at anneal time t_{A1}) up to the points 311, 321, and 333 (representing the maximum tuning ranges), represent “nominal tuning regions” in which the junction resistances of the Josephson junctions increase with laser annealing. On the other hand, the portions of the calibration curves 310, 320, and 330 following the points 311, 321, and 333 (representing the maximum tuning ranges) represent “reverse shift tuning regions” in which the junction resistances of the Josephson junction plateau and start to decrease. In some embodiments, when laser tuning Josephson junctions, it is preferable to tune in the “nominal tuning regions” as identified in the tuning calibration curves shown in FIG. 3. In other embodiments, tuning in the “reverse shift tuning regions” may be implemented to achieve bidirectional shifting as needed. The calibration data shown in FIG. 3 can be analyzed to generate tuning curves using techniques as explained in further detail below.

FIGS. 4A and 4B illustrate a flow diagram of a calibration process for obtaining calibration data for use in laser tuning Josephson junctions, according to another exemplary embodiment of the disclosure. The calibration process flow of FIGS. 4A and 4B is based on the high-level calibration process flow of FIG. 2. In particular, FIG. 4A illustrates an exemplary process for performing laser annealing calibration tests on Josephson junction to obtain calibration data, and FIG. 4B illustrates an exemplary process for using the calibration data (obtained from the laser annealing calibration tests) to determine tuning curves and maximum tuning ranges for different laser power setting and associated anneal times. In some embodiments, FIG. 4A illustrates laser annealing calibration tests that can be performed using the laser annealing system 100 of FIG. 1 with the control system 110 executing a calibration algorithm.

In particular, referring now to FIG. 4A, a quantum chip is placed on the X-Y-Z stage 142 of the prober unit 140, and the control system 110 commences a calibration process to perform automated laser annealing calibration tests (block 400). As noted above, the quantum chip comprises a collection of test Josephson junctions which are representative of actual Josephson junctions that are to be laser tuned using the calibration data obtained from the calibration process, wherein the quantum chip can be a sister chiplet or a quantum chip having a collection of test Josephson junctions that reside (e.g., in a kerf region) on the same quantum chip which has the Josephson junctions that are to be tuned.

The collection of test Josephson junctions are partitioned into multiple groups for tuning calibration (block 401). The number of groups will correspond to the number of different combinations of discrete laser power settings and anneal times, that are selected for the laser annealing calibration tests. For example, assuming that the laser annealing calibration tests are performed using three (3) discrete laser power settings P₁, P₂, and P₃ (e.g., P₁=1.80 W, P₂=2.0 W, P₃=2.2 W) and seven (7) different anneal times (e.g., 0.5 s, 1.0 s, 2.0 s, 5.0 s, 10.0 s, 20.0 s, and 100 s) for each discrete laser power setting, the collection of test Josephson junctions are partitioned into 21 groups, wherein each group would have a desired number of test Josephson junctions (e.g., 3, 4, 5, etc.) desired to obtain calibration data with statistical significance.

The calibration process selects an initial group of test Josephson junctions for laser annealing to obtain calibration data (block 402) and proceeds to perform in-situ resistance measurements to measure the initial junction resistance (Rᵢₙᵢₜᵢₐₗ) of each test Josephson junction of the given group (block 403). For example, in some embodiments, the in-situ resistance measurements are performed using a 4-wire (Kelvin) resistance measurement process as discussed herein. The calibration process selects a given combination of laser power and anneal time to laser anneal each test Josephson junction in the given group (block 404). For example, for the given calibration iteration, the calibration process can select the low laser power setting P₁ and anneal time t_{A1}=0.5 s as the initial selection, wherein for each subsequent calibration iteration on remaining groups test Josephson junction, the calibration process can select a different combination of laser power setting and anneal time, e.g., P₁ and anneal time t_{A2}=1.0, P₁ and anneal time t_{A3}=2.0 s, etc.

The calibration process proceeds to laser anneal each test Josephson junction of the given group, in succession, at the selected combination of laser power and anneal time (block 405). Next, in-situ resistance measurements are performed to remeasure the junction resistances of each test Josephson junction of the given group to determine the current junction resistance R_{current} of each test Josephson junctions following the laser anneal operations (block 407). In some embodiments, a given time delay is imposed after the laser annealing operations (block 405) before remeasuring the junction resistances (block 406) to allow the test Josephson junctions to settle to a stable resistance state following the completion of a laser annealing of the test Josephson junctions. The time delay can be on the order of, e.g., a minute (or minutes), or an hour (or hours), etc., or any time as needed to allow the test Josephson junctions to settle to a stable resistance state following the completion of a laser annealing.

Following the resistance remeasurements (block 406), the resistance measurement data (e.g., Rᵢₙᵢₜᵢₐₗ and R_{current}) for each test Josephson junctions of the given group is used to determine an amount of junction resistance shift that occurs as a result of the laser annealing the test Josephson junctions at the given combination of laser power and anneal time (block 407). For example, as noted above, in some embodiments, the amount of junction resistance shift ΔR for a given test Josephson junction is determined as: ΔR=R_{current}−Rᵢₙᵢₜᵢₐₗ (and with a “resistance shift percentage” determined as:

$$Δ R \% = \frac{Δ R}{{R}_{initial}} \times 100 \% ) .$$

The resistance measurement data (e.g., Rᵢₙᵢₜᵢₐₗ, R_{current} and computed ΔR) for each test Josephson junction at the given combination of laser power anneal time is stored (block 407) for subsequent access and analysis.

Next, the calibration process determines whether there are one or more remaining groups of test Josephson junctions to perform laser annealing calibration tests using other combinations of laser power and anneal time (block 408). If there are one or more are one or more remaining groups of test Josephson junctions to be tested (affirmative determination in block 408), the calibration process selects a next group of test Josephson junctions (return to block 402) and repeats the laser annealing calibration test (repeat block 403, 404, 405, 406, and 407) on the next selected group of test Josephson junctions using a next selected combination of laser power and anneal time.

At the completion of the laser annealing calibration tests of FIG. 4A, the calibration process comprises a collection of computed ΔR data or ΔR % data, which is utilized to compute calibration tuning metrics, e.g., (i) compute tuning curves that represent tuning rates of the test Josephson junctions for the each of the laser power settings as a function of anneal time, and (ii) determine maximum tuning ranges (e.g., maximum ΔR %) for each of the laser power settings. For example, referring to FIG. 4B, the calibration process commences a tuning calibration data computation process (block 410) to compute tuning curves and maximum tuning ranges for each of the laser power settings.

In some embodiments, as an initial step, the calibration process determines tuning range data for each group of test Josephson junctions for each combination of laser power and anneal time (block 411). In some embodiments, the tuning range data is determined by computing an average ΔR % for each combination of laser power and annal time using the collection of ΔR % data determined for the respective group of test Josephson junctions that were laser annealed at the given combination of laser power and anneal time. By way of example, referring again to the exemplary embodiment of FIG. 3, as noted above, the point 331 of the calibration curve 330 has a ΔR % value of approximately 15%, which represents that the given group of test Josephson junctions, which were laser annealed at the laser power setting P₃ for anneal time of t_{A1}, had an average ΔR % of approximately 15%. It is to be noted that the tuning range data computed in block 411 comprises data points that represent calibration curves such as shown in FIG. 3.

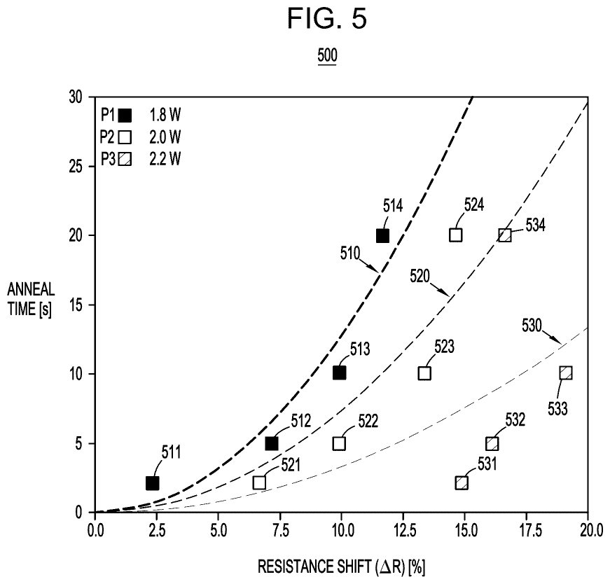

The computed tuning range data is utilized to generate tuning curves for the laser power settings (block 412). For example, in some embodiments, the tuning curve for a given laser power setting is determined using a curve fitting process to fit the tuning range (average ΔR %) data points for the given laser power setting to a curve using a polynomial curve fitting process (e.g., a second order (or higher order) polynomial curve fitting process). In other embodiments, the tuning curve for a given laser power setting is determined using a nonlinear regression process to fit the tuning range (average ΔR %) data points for the given laser power setting to a curve using, for example, a logarithmic, or inverse exponential curve. Exemplary methods for computing tuning curves will be discussed in further detail below in conjunction with, e.g., FIG. 5.

Further, the computed tuning range data is utilized to determine a maximum tuning range for each laser power setting (block 413). In some embodiments, the maximum tuning range for a given laser power setting is determined to be the greatest average ΔR % obtained for a given group of test Josephson for a given anneal time at the given laser power setting. By way of example, referring again to the exemplary embodiment of FIG. 3, as noted above, the data point 333 of the calibration curve 330 represents a maximum tuning range of ˜19% that is achieved at the high laser power setting P₃ and anneal time t_{A3}, the data point 321 of the calibration curve 320 represents a maximum tuning range of ˜14% that is achieved at the medium laser power setting P₂ and anneal time t_{A4}, and the data point 311 of the calibration curve 310 represents a maximum tuning range of ˜12% that is achieved at the low laser power setting P₁ and anneal time t_{A5}. In other embodiments, the maximum tuning range for a given laser power setting is determined using an interpolation function (polynomial, logarithmic, or the like) where the maximum value may be extracted from the extrema of a curve resulting from a linear or nonlinear regression curve fitting process.

The calibration process stores the computed tuning curves and determined maximum tuning ranges in a database of calibration data (e.g., database 115, FIG. 1). The tuning curves and determined maximum tuning ranges comprise tuning calibration data that is subsequently used to calibrate laser annealing operations for accurate tuning of Josephson junctions. The tuning calibration data computation process terminates (block 415) after all desired tuning curves and maximum tuning ranges are determined from the tuning range data collected from the laser annealing calibration tests.

FIG. 5 depicts a graph 500 which illustrates tuning curves that are determined using tuning range data obtained from laser annealing calibration tests, according to an exemplary embodiment of the disclosure. In particular, the graph 500 illustrates a plurality of calibration tuning curves 510, 520, and 530 which represent junction resistance shift (ΔR) % (or tuning %) as a function of anneal time for discrete laser power levels (e.g., P₁, P₂, and P₃). For example, the first tuning curve 510 represents an amount of junction resistance shift (ΔR) % as a function of anneal time at the low laser power setting P₁ (e.g., 1.80 W). The second tuning curve 520 represents an amount of junction resistance shift (ΔR) % as a function of anneal time at the medium laser power setting P₂ (e.g., 2.0 W). The third tuning curve 530 represents an amount of junction resistance shift (ΔR) % as a function of anneal time at the high laser power setting P₃ (e.g., 2.2 W).

In an exemplary embodiment, the first tuning curve 510 is computed using a curve fitting process to fit a plurality of tuning range data points (e.g., 511, 512, 513, and 514) to a polynomial curve using a second order polynomial curve fitting process. As discussed above, the tuning range data points 511, 512, 513, and 514 each correspond to a respective computed average ΔR % of the collection of ΔR % data obtained for the respective group of Josephson junctions which are shot at the given laser power setting P₁ for the associated anneal times 2.0 s, 5.0 s, 10.0 s, and 20.0 s, respectively. Similarly, the second tuning curve 520 is computed using the same second order polynomial curve fitting process to fit a plurality of tuning range data points (e.g., 521, 522, 523, and 524) to the second order polynomial curve represented by the tuning curve 520. The tuning range data points 521, 522, 523, and 524 each correspond to a respective computed average ΔR % of the collection of ΔR % data obtained for the respective group of Josephson junctions which are shot at the given laser power setting P₂ for the associated anneal times 2.0 s, 5.0 s, 10.0 s, and 20.0 s, respectively.

Further, the third tuning curve 530 is computed using the same second order polynomial curve fitting process to fit a plurality of tuning range data points (e.g., 531, 532, 533, and 534) to the second order polynomial curve represented by the tuning curve 530. The tuning range data points 531, 532, 533, and 534 each correspond to a respective computed average ΔR % of the collection of ΔR % data obtained for the respective group of Josephson junctions which are shot at the given laser power setting P₃ for the associated anneal times 2.0 s, 5.0 s, 10.0 s, and 20.0 s, respectively. The exemplary tuning curves 510, 520, and 530 can be used to estimate a given anneal time that is needed at a given laser power setting to tune a Josephson junction to a target ΔR %, as will be discussed in further detail below. In some embodiments, the tuning curves 510, 520, and 530 may be determined using at least a portion of the existing tuning range data from laser annealing calibration tests, and correspond in part to the curves 310, 320, and 330, in a manner where the scaling of anneal time is linearized such that the depicted second-order curve fitting process may be accurately performed. In other embodiments, the tuning curves 510, 520, and 530 may be determined using new tuning range data obtained from a separate set of laser annealing calibration tests, using another set of test (dummy) Josephson junctions that reside on the same quantum chip to be tuned, or in other embodiments, can be Josephson junctions of qubits that are formed on a sister chiplet from the same fabrication process.

In some embodiments, the tuning calibration data that is obtained and computed using the exemplary process flow of FIGS. 4A and 4B, for example, can be utilized to calibrate a LASIQ process for laser annealing the Josephson junctions of superconducting qubits, post-fabrication, to selectively tune the transition frequencies of the superconducting qubits by laser tuning the junction resistances of the respective Josephson junctions. An exemplary LASIQ process can be performed, post-fabrication, to selectively tune fixed-frequency qubits of a given qubit lattice into desired frequency patterns which are configured to increase the collision-free yield of fixed-frequency qubit lattices.

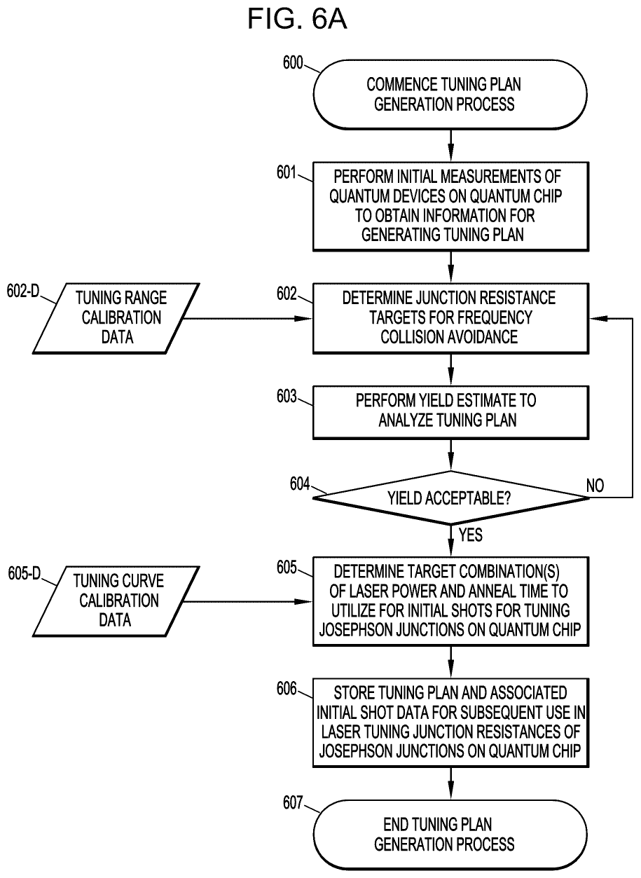

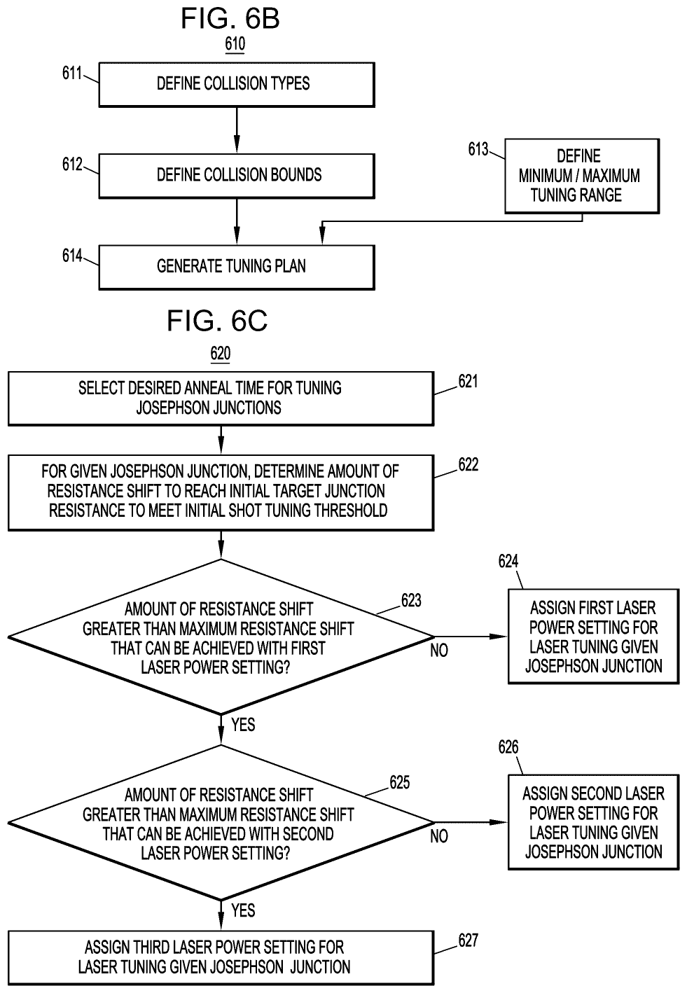

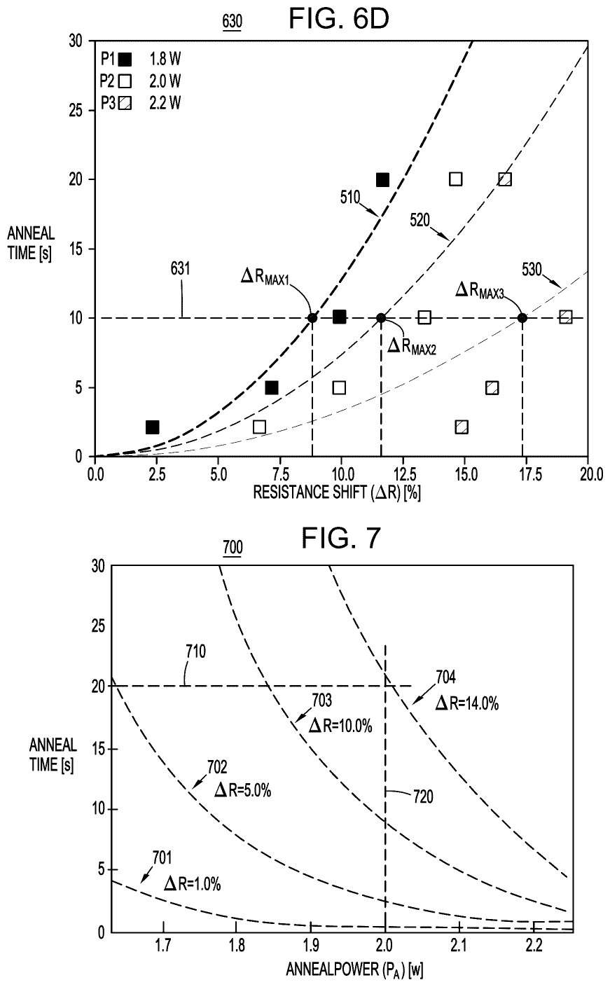

For example, FIG. 6A illustrates process for utilizing tuning calibration data of Josephson junction to calibrate a process (e.g., LASIQ process) for tuning transition frequencies of superconducting qubits, according to an exemplary embodiment of the disclosure. For example, FIG. 6A illustrates a flow diagram of a process for generating a tuning plan for laser tuning Josephson junctions of superconducting qubits to selectively trim qubit transition frequencies. In some embodiments, FIG. 6A illustrates process that can be performed by the control system 110 of FIG. 1 commencing and executing a tuning plan generation process using tunning calibration data in the database 115, and the laser annealing apparatus to perform Josephson junction resistance measurement and laser tuning operations, as discussed in further detail below.

The control system 110 can commence and execute an automated tuning plan tuning process (block 600). A quantum chip which comprises a lattice array of superconducting qubits to be LASIQ tuned is placed on the X-Y-Z stage 142 of the prober unit 140, and the control system 110 commences an automated process to perform initial measurements of the quantum devices on the quantum chip to obtain relevant information for use in generating a frequency tuning plan (block 601). For example, the initial measurements performed comprise junction resistance measurements that are performed using the prober unit 140 to measure the initial junction resistances (Rᵢₙᵢₜᵢₐₗ) of the Josephson junctions of the superconducting qubits. In some embodiments, the junction resistance measurements are performed using a 4-wire (Kelvin) resistance measurement process as discussed herein.

Next, the tuning plan generation process determines respective target junction resistances (R_{target}) for the Josephson junctions of the superconducting qubit for laser tuning the transition frequencies of the superconducting qubits to achieve frequency collision avoidance (block 602). More specifically, in some embodiments, the tuning plan generation process determines the respective target junction resistances (R_{target}) for the Josephson junctions based on the initial measured junction resistances (Rᵢₙᵢₜᵢₐₗ) of the Josephson junctions and tuning range calibration data 602-D associated with Josephson junctions of the qubits. The tuning range calibration data 602-D provides information regarding the maximum tuning range (e.g., maximum ΔR %) that can be achieved for tuning the Josephson junctions of the superconducting qubits, wherein the tuning range calibration data 602-D coupled with the initial measured junction resistances (Rᵢₙᵢₜᵢₐₗ) of the Josephson junctions provide constraints on the algorithm computations that determine the target junction resistances (R_{target}) of the Josephson junction for a given frequency plan. An exemplary process for generating a frequency tuning plan will be discussed in further detail below in conjunction with FIG. 6B.

When generating a frequency tuning plan, the goal is to arrange the qubit transition frequencies into a pattern where there are no frequency collisions among neighboring qubits. Typically, such neighboring qubits may, for example, be nearest-neighbor qubits which are in direct connection with each other, or next-nearest-neighbor qubits which are separated by a connecting qubit. Higher degrees of neighbor separation may be considered depending on the specific use case of the processor. In other words, the frequency tuning plan is designed to mitigate frequency crowding by tuning the transition frequency f₀₁ of a given superconducting qubit in some target frequency range where transition frequency f₀₁ of the given superconducting qubit does not conflict (e.g., collide) with the transition frequency of a neighboring superconducting qubit. In doing so, the frequency tuning plan generation process utilizes the initial measured junction resistances (Rᵢₙᵢₜᵢₐₗ) of the Josephson junctions, together with the tuning range calibration data (e.g., the maximum tuning range ΔR % data) to know the tuning constraints for laser tuning the junction resistances of the Josephson junctions which, in turn, places constraints on the frequency tuning of the superconducting qubits. This data allows the frequency tuning plan generation process to know how much the transition frequencies of the qubits can be trimmed, and thereby generate a suitable frequency tuning plan based on such tuning constraints.

After generating a frequency tuning plan, the process performs a yield estimate process to analyze the frequency tuning plan (block 603). In some embodiments, the yield estimate process is performed using Monte Carlo simulations to statistically determine how many frequency collisions are expected based on the given frequency tuning plan. Typically, an ideal frequency tuning plan cannot be achieved, but for a given qubit lattice architecture (e.g., heavy hexagonal lattice, square lattice, etc.), there is an ideal frequency pattern that can be utilized to minimize the number of frequency collisions, but nevertheless, an ideal frequency tuning plan is difficult to achieve because of the limited tuning ranges of Josephson junctions. However, having a priori knowledge of expected maximum junction resistance tuning ranges (via the tuning range calibration data 602-D) provides useful information that enables the frequency tuning plan generation process to determine an optimal frequency tuning plan for the given qubit lattice with qubit Josephson junctions with the added constraint of anticipated tuning ranges correspond to the calibration data 602-D. The tuning range of the Josephson junction therefore poses an additional practical constraint that must be satisfied in any tuning plan that is used to mitigate frequency collisions.

After analyzing the frequency tuning plan, a determination is made as to whether the yield estimate of the frequency tuning plan is acceptable (block 604). If the yield estimate of the frequency tuning plan is deemed unacceptable (negative determination in block 604), a new frequency tuning plan will be generated using a new set of tuning plan parameters (return to block 602). On the other hand, if the yield estimate of the frequency tuning plan is deemed acceptable (affirmative determination in block 604), the process proceeds to determine the target combinations of laser power and anneal times to utilize for performing the initial “shots” for tuning the Josephson junctions of the superconducting qubits on the quantum chop (block 605).

More specifically, in some embodiments, the initial “shot” (e.g., combination of laser power and anneal time) for laser tuning a Josephson junction is performed so that the junction resistance is increased from the initial junction resistance Rᵢₙᵢₜᵢₐₗ to an initial target junction resistance (denoted R_{intial_target}) which results in an initial amount of resistance shift (denoted ΔRᵢₙᵢₜᵢₐₗ%), where:

$$Δ {R}_{initial} \% = \frac{Δ {R}_{target} - Δ {R}_{initial}}{Δ {R}_{target}} \times 100 \% ≅ x ( e . g . , x = 50 \% ) ,$$

where ΔR_{target} denotes a difference between the final target junction resistance (R_{target}) and the initial measured junction resistance (Rᵢₙᵢₜᵢₐₗ) of the Josephson junction before the first anneal operation (i.e., ΔR_{target}=R_{target}−Rᵢₙᵢₜᵢₐₗ), and where ΔRᵢₙᵢₜᵢₐₗ=R_{initial_target}−Rᵢₙᵢₜᵢₐₗ. In this regard, the value ΔRᵢₙᵢₜᵢₐₗ% is also determined as:

$$Δ {R}_{initial} \% = \frac{{R}_{target} - {R}_{initial\_target}}{Δ {R}_{target}} \times 100 \% .$$

This allows the given Josephson junction to be laser tuned to an initial target resistance R_{initial_target} which is about 50% to the final target junction resistance R_{target} of the given Josephson junction, as specified by the accepted frequency tuning plan. In this exemplary method, ΔRᵢₙᵢₜᵢₐₗ=50% is chosen to appreciably tune the Josephson junctions towards target, while mitigating the risk of overshooting the targets. Shots subsequent to the first (initial) shot may be tailored to gradually approach junction resistance targets in a progressive and asymptotic manner. As shown in FIG. 6A, the target combination of laser power and anneal time to utilize for performing the initial “shot” for a given Josephson junction of a given qubit is determined at least based in part on tuning curve calibration data 605-D. For example, as explained in further detail below in conjunction with FIG. 6C and FIG. 7, the determination in block 605 can be performed by selecting a target maximum anneal time (e.g., 10 s), and then utilizing the tuning curves to determine a minimum laser power setting which allows the given Josephson junction to be initially tuned by the amount ΔRᵢₙᵢₜᵢₐₗ% for an anneal time that is no greater than the selected target maximum anneal time.

Once the target combinations of laser power and anneal time (laser tuning parameters) for the initial “shots” are determined for the respective Josephson junctions, the frequency tuning plan data and associated laser tuning parameters for the Josephson junctions are stored for subsequent access and use in performing LASIQ tuning operations, as discussed in further detail below in conjunction with FIG. 8.

FIG. 6B illustrates a flow diagram of a method for generating a frequency tuning plan, according to an exemplary embodiment of the disclosure. In some embodiments, FIG. 6B illustrates an exemplary process 610 for generating a frequency tuning plan, which can be implemented in block 602 of FIG. 6A. As noted above, a frequency tuning plan is generated to perform LASIQ tuning of the transition frequencies of superconducting qubits to avoid frequency collisions in the qubit lattice when performing gate operations (e.g., single gate operations, multi-gate operations (e.g., two-qubit gate entanglement operations, etc.) on a quantum chip (e.g., quantum processor). The process involves defining/determining a plurality of key constraints for a given frequency tuning plan including defining collision types (block 611), defining collision bounds (block 613), and defining tuning ranges (e.g., minimum and maximum tuning ranges). In some embodiments, as noted above, the maximum tuning ranges are determined based on the tuning range calibration data 602-D that is determined using the calibration techniques as discussed herein for determining the maximum tuning ranges of the qubit Josephson junctions.

FIG. 6C illustrates a flow diagram of a method for utilizing laser tuning calibration data to determine laser annealing parameters for performing initial laser tuning operations on Josephson junctions, according to an exemplary embodiment of the disclosure. In some embodiments, FIG. 6C illustrates an exemplary process 620 for utilizing laser tuning calibration data to determine laser annealing parameters for performing initial laser tuning operations on Josephson junctions given a frequency tuning plan, which can be implemented in block 605 of FIG. 6A. In some embodiments, as noted above, the laser tuning calibration data is utilized to determine the laser power and anneal time for performing an initial laser annealing operation (initial “shot”) on a given Josephson junction so that the given Josephson junction can be laser tuned to about 50% of ΔR_{target} (where ΔR_{target}=R_{target}−Rᵢₙᵢₜᵢₐₗ) by the initial laser annealing operation. As noted above,

$$Δ {R}_{initial} \% = \frac{{R}_{target} - {R}_{initial\_target}}{Δ {R}_{target}} \times 100 \% ≅ x ,$$

where x=50% or some other desired value which is less than or greater than 50%, depending on the application. Moreover, the amount of junction resistance shift ΔR % needed to shift the junction resistance of a given Josephson junction from Rᵢₙᵢₜᵢₐₗ to Rᵢₙᵢₜᵢₐₗ target for the initial “shot” is determined as:

$$Δ R \% = \frac{Δ R}{{R}_{initial}} \times 100 \% = \frac{{R}_{initial\_target} - {R}_{initial}}{{R}_{initial}} \times 100 \% .$$

Referring to FIG. 6C, an initial step involves selecting a desired anneal time for laser tuning the Josephson junctions (block 621). In some embodiments, it is desirable to laser tune the Josephson junctions by performing laser anneal operations using the same anneal time (e.g., 10 seconds). In this regard, in some embodiments, the anneal time for laser tuning is initially selected (e.g., 10 seconds), and the process proceeds to determine and assign respective minimum laser power settings to the Josephson junctions, which are sufficient for tuning the Josephson junctions to their respective initial target junction resistance R_{initial_target} without any significant undershoot or overshoot.

In particular, for a given Josephson junction to be laser tuned, the process determines an amount of resistance shift needed to reach the initial resistance target Rᵢₙᵢₜᵢₐₗ_target in order to meet the initial shot tuning threshold, e.g., ΔRᵢₙᵢₜᵢₐₗ%≅50% (block 622). For example, assume for the sake of simplicity that for the given Josephson junction, Rᵢₙᵢₜᵢₐₗ=100, R_{target}=120, and ΔR_{target}=R_{target}−Rᵢₙᵢₜᵢₐₗ=20. For an initial shot tuning shift threshold of ΔRᵢₙᵢₜᵢₐₗ%=50%, the initial resistance target R_{initial_target} can be computed as:

$$Δ {R}_{initial} \% = \frac{{R}_{target} - {R}_{initial\_target}}{Δ {R}_{target}} \times 100 \% or 0.5 = \frac{120 - {R}_{initial\_target}}{20} ,$$

where R_{initial_target}=110. Next, the amount of junction resistance shift ΔR % needed to shift the junction resistance of the given Josephson junction from Rᵢₙᵢₜᵢₐₗ=100 to R_{initial_target}=110 for the initial “shot” is determined as:

$$Δ R \% = \frac{{R}_{initial\_target} - {R}_{initial}}{{R}_{initial}} \times 100 \% = \frac{110 - 100}{100} \times 100 \% = 10 \% .$$

Next, the determined junction resistance shift ΔR % is utilized to determine a given power level setting to assign to the given Josephson junction based on the selected anneal time. For example, a determination is made as to whether the computed junction resistance shift ΔR % for the given Josephson junction is greater than a first maximum junction resistance shift ΔR_{MAX1} that can be achieved with a first (lowest) laser power setting (e.g., P₁=1.8 W) for the selected anneal time (block 623). If it is determined that the computed junction resistance shift ΔR % is not greater than the first maximum junction resistance shift ΔR_{MAX1} (negative determination in block 623), the process assigns the first laser power setting P₁ for laser tuning the given Josephson junction (block 624).

On the other hand, if it is determined that the computed junction resistance shift ΔR % is greater than the first maximum junction resistance shift ΔR_{MAX1} (affirmative determination in block 623), the process proceeds to determine whether the computed junction resistance shift ΔR % for the given Josephson junction is greater than a second maximum junction resistance shift ΔR_{MAX2} that can be achieved with a second (middle) laser power setting (e.g., P_{2=2.0} W) for the selected anneal time (block 625). If it is determined that the computed junction resistance shift ΔR % is not greater than the second maximum junction resistance shift ΔR_{MAX2} (negative determination in block 625), the process assigns the second laser power setting P₂ for laser tuning the given Josephson junction (block 626). On the other hand, if it is determined that the computed junction resistance shift ΔR % is greater than the second maximum junction resistance shift ΔR_{MAX2} (affirmative determination in block 625), the process assigns the third (high) laser power setting P₃ for laser tuning the given Josephson junction (block 627).

By way of further example, FIG. 6D illustrates a process of using calibration tuning curves to determine a power level setting for laser annealing a Josephson junction based on a selected anneal time and initial tuning shift threshold, according to an exemplary embodiment of the disclosure. In particular, FIG. 6D illustrates an exemplary process 630 to determine a power level setting based on the exemplary process flow of FIG. 6C using the exemplary tuning curves 510, 520, and 530 as described above in conjunction with FIG. 5. For example, as shown in FIG. 6D, a horizontal dashed line 631 represents a selected anneal time of 10 seconds (selection in block 621, FIG. 6C). The horizontal dashed line 631 intersects the first tuning curve 510, the second tuning curve 520, and the third tuning curve 530 at respective points ΔR_{MAX1}, ΔR_{MAX2}, and ΔR_{MAX3}, wherein ΔR_{MAX1}<ΔR_{MAX2}<ΔR_{MAX3}.

The point ΔR_{MAX1} represents a maximum amount of junction resistance shift ΔR % that can be achieved for a given Josephson junction by laser tuning the given Josephson junction at the laser power setting P₁ for the anneal time of 10 s. The point ΔR_{MAX2} represents a maximum amount of junction resistance shift ΔR % that can be achieved for a given Josephson junction by laser tuning the given Josephson junction at the middle laser power setting P₂ for the anneal time of 10 s. The point ΔR_{MAX3} represents a maximum amount of junction resistance shift ΔR % that can be achieved for a given Josephson junction by laser tuning the given Josephson junction at the laser power setting P₃ for the anneal time of 10 s. For achieving a ΔR %=10% tuning shift of the junction resistance of a given Josephson junction from Rᵢₙᵢₜᵢₐₗ to R_{initial_target} (as in the above example where Rᵢₙᵢₜᵢₐₗ=100 and R_{initial_target}=110), the laser power setting P₁ cannot be utilized as ΔR_{MAX1}<ΔR %=10%. On the other hand, the laser power setting P₂ can be utilized since ΔR_{MAX1}>ΔR %=10%. Therefore, FIG. 6D illustrates that the laser power setting P₂ can be selected as a minimum laser power setting to achieve a ΔR %=10% for an anneal time of 10 s. Once the power levels are determined for each junction, the tuning may progress by selecting the anneal time such that each junction is tuned to about 50% of ΔR_{target}. The process described here represents an exemplary embodiment shown in FIGS. 6C and 6D. In other embodiments of this method, the anneal power setting may be determined based on a selected total completion anneal time of, for example, 10 s (rather than the anneal time to an initial target junction resistance corresponding to 50% completion). In this case, rather than select the power based on R_{initial_target}, the power is based instead on R_{target}, such that P₁, P₂, and P₃ may be selected in a similar manner as described above. Once the power levels are selected, the tuning may progress by selecting the anneal time such that each junction is tuned to about 50% of ΔR_{target}.

It is to be noted that FIGS. 5 and 6D illustrate exemplary embodiments of tuning curves which correspond to a plurality of discrete laser powers, wherein laser power can be selected based on a desired anneal time and ΔR %. In other embodiments, tuning curves can be generated and utilized to represent tuning calibration data in other ways. For example, FIG. 7 depicts a graph 700 which illustrates tuning curves that are determined using tuning range data obtained from laser annealing calibration tests, according to another exemplary embodiment of the disclosure. In particular, the graph 700 illustrates a plurality of calibration tuning curves 701, 702, 703, and 704, which represent junction resistance shift (ΔR) % (or tuning %) as a function of anneal time (Y-axis) and laser power (X-axis). For example, the first tuning curve 701 represents a value of ΔR %=1.0% as a function of anneal time and laser power. The second tuning curve 702 represents a value of ΔR %=5.0% as a function of anneal time and laser power. The third tuning curve 703 represents a value of ΔR %=10.0% as a function of anneal time and laser power. The fourth tuning curve 704 represents a value of ΔR %=14.0% (e.g., maximum tuning range) as a function of anneal time and laser power.

The graph 700 of calibration tuning curves 701, 702, 703, and 704 can be used to select an anneal time and laser power based on a target ΔR %, or select a laser power based on a desired anneal time and target ΔR %. For example, FIG. 7 illustrates a horizontal dashed line 710 which represents a selected anneal time of 20 seconds. The points at which the horizontal dashed line 710 intersect the respective tuning curves 702, 703, and 704 ΔR of respective ΔR % values can be used to determine the laser power to achieve a desired ΔR %. Essentially, the graph 700 allows any combination of laser power and anneal time to be selected to achieve the same ΔR %. As an example, by selecting a target laser power, e.g., 2.0 W, the anneal times to achieve each of the ΔR % values represented by the tuning curves 701, 702, 703, and 704 can be determined by the points at which a vertical line 720 at the selected power level 2.0 intersects the tuning curves 701, 702, 703, and 704.

It is to be appreciated that the exemplary calibration techniques as discussed herein are designed to obtain tuning calibration data which represents laser tuning characteristics of Josephson junctions. While Josephson junctions on a given quantum chip typically tune at different rates, the tuning rates of such Josephson junctions are generally similar. In this regard, the tuning calibration data that is obtained by measuring and analyzing changes in junction resistances of test Josephson junctions as a function of different laser powers and anneal times, provides a good baseline of calibration information that can be utilized to calibrate laser annealing operations to laser tune actual Josephson junctions that are fabricated using the same or similar processes of the test Josephson junctions. As noted above, the tuning calibration data (e.g., tuning range data) associated with Josephson junctions can be utilized in a process to generate a frequency tuning plan for LASIQ tuning of superconducting qubits which comprises Josephson junctions with tuning characteristics represented by the tuning calibration data. The frequency tuning plan specifies respective R_{target} values for the Josephson junctions of the qubits to achieve the target transition frequencies of the qubits as specified by the frequency tuning plan. In addition, the tuning calibration data (e.g., tuning rate) can be utilized to estimate a target combination of laser power and anneal time for performing an initial laser annealing operation (initial shot) on a given Josephson junction, such that the target combination of laser power and anneal time allows the given Josephson junction to be initially tuned to about 50% of resistance shift from the initial junction resistance Rᵢₙᵢₜᵢₐₗ to the target junction resistance R_{target} of the given Josephson junction.

FIG. 8 illustrates a flow diagram of a method for tuning Josephson junctions, according to an exemplary embodiment of the disclosure. In some embodiments, FIG. 8 illustrates an automated tuning process, which can be performed using the laser annealing system 100 of FIG. 1, to laser tune Josephson junctions to respective R_{target} values and thereby tune superconducting qubits in a qubit lattice on a quantum chip to respective target transition frequencies as specified by a frequency tuning plan. A quantum chip is placed on the X-Y-Z stage 142 of the prober unit 140, and the control system 110 commences an automated tuning process (block 800). The quantum chip comprises a plurality of superconducting qubits arranged in a given qubit lattice. The tuning process accesses a frequency tuning plan generated for the given qubit lattice, and tuning calibration data associated with the Josephson junctions of the superconducting qubits (bock 801). The frequency tuning plan specifies respective R_{target} values for the Josephson junctions, and the tuning calibration data which is used to determine laser power setting and anneal times for laser annealing the Josephson junctions of the superconducting qubits.

The automated tuning process selects an initial Josephson junction of an initial superconducting qubit in the lattice and moves to the selected Josephson junction (block 802). In particular, the control system 110 moves the X-Y-Z stage 142 to place the initial Josephson junction into the FOV of the microscope unit 130. In particular, the control system 110 moves the X-Y-Z stage 142 to place the initial Josephson junction into the FOV of the microscope unit 130. The tuning process initiates control operations to cause the microscope unit and the probe unit to perform a focus and alignment process to ensure a proper focus to the focal plane and proper alignment of the target Josephson junction within the FOV of the microscope unit 130 for the purpose of performing an in-situ Josephson junction resistance measurement (block 803). The focus ensures that the sample plane (e.g., the plane which contains the target Josephson junction) is at the focal plane (i.e., plane of focus) of the objective lens 137. The focus can be adjusted by adjusting the Z position of the X-Y-Z stage 142. The alignment to the Josephson junction can be performed using a machine learning pattern recognition process to align the Josephson junction to the center of the FOV.

Next, the tuning process proceeds to measure the junction resistance of the target Josephson junction (block 804). In particular, the tuning process measures an initial junction resistance Rᵢₙᵢₜᵢₐₗ of the Josephson junction. In some embodiments, the electrical probes 144 are landed on the contact pads with a fixed displacement distance and overdrive to ensure proper contact (e.g., a stable, low resistance contact). In some embodiments, the electrical probes 144 are vertically moved downward to contact the tips of the electrical probes 144 to the contact pads on the quantum chip. In other embodiments, the positions of the electrical probes 144 remain fixed, and the Z position of the X-Y-Z stage 142 is moved upward so that the contact pads on the quantum chip are moved into contact with the tips of the electrical probes 144 (in which case a second focus and alignment step can be performed subsequent to the junction resistance measurement and prior to the initial laser annealing step as discussed below).

In some embodiments, an in-situ junction resistance measurement is performed by contacting the electrical probes with contact pads of the target Josephson junction and then applying a test DC voltage to the Josephson junction to generate and measure a resulting DC current to determine the junction resistance. In some embodiments, as noted above, the junction resistance is determined using a 4-wire (Kelvin) probe resistance measurement operation, whereby a constant current is passed through the Josephson junction, and a resulting voltage across the Josephson junction is measured, and the junction resistance is determined based on the magnitude of the constant current and the measured voltage. In some or other embodiments, the junction resistance is determined using a 4-wire (Kelvin) probe resistance measurement operation, whereby a constant voltage is sourced across the Josephson junction, and the resulting current is measured, and the junction resistance is determined based on the magnitude of the constant voltage and the measured current. Moreover, in some embodiments, contact resistance and contact stability checks are initially performed, prior to performing the junction resistance measurement, to ensure that the contact resistance is below a given threshold, and to ensure that the contact between the electrical probe and the contact pads of the Josephson junction and stable and not intermittent.

Next, the tuning process initiates control operations to cause the microscope unit 130 and the prober unit 140 to perform a focus and alignment process to ensure a proper focus to the focal plane and proper alignment of the target Josephson junction within the FOV of the microscope unit 130 for the purpose of performing a laser anneal operation (block 805). The tuning process proceeds to determine a target combination of laser power and anneal time to perform an initial laser anneal operation (initial shot) to achieve an initial junction resistance shift ΔRᵢₙᵢₜᵢₐₗ=R_{initial_target}−Rᵢₙᵢₜᵢₐₗ to reach an initial tuning threshold ΔRᵢₙᵢₜᵢₐₗ% (block 806). As noted above, in some embodiments, the initial tuning threshold ΔRᵢₙᵢₜᵢₐₗ% is determined as

$$Δ {R}_{initial} \% = \frac{{R}_{target} - {R}_{initial\_target}}{Δ {R}_{target}} \times 100 \% ≅ x ,$$

where in some embodiments x=50%. The target combination of laser power and anneal time to perform the initial laser anneal operation is determined based on the measured Rᵢₙᵢₜᵢₐₗ, the specified R_{target}, and the tuning calibration data (e.g., calibration tuning rates), using methods as discussed above, the details of which will not be repeated.

The tuning process performs the initial laser anneal operation (initial shot) on the given Josephson junction using the determined combination of laser power and anneal time for the initial shot (block 807). After completion of the initial laser anneal operation for the given Josephson junction, the tuning process determines whether there are any remaining Josephson junctions that need to be laser tuned to a target ΔRᵢₙᵢₜᵢₐₗ using an initial laser anneal operation (block 808). If there are one or more Josephson junctions that need to be to be tested (affirmative determination in block 808), the tuning process selects a next Josephson junction of a next superconducting qubit to be tuned (return to block 802) and repeats the laser tuning operations (repeat blocks 803, 804, 805, 806, and 807). On the other hand, if it is determined that there are no remaining Josephson junctions that need to be laser tuned to a target ΔRᵢₙᵢₜᵢₐₗ using an initial laser anneal operation (negative determination in block 808), the tuning process proceeds to tune each Josephson junction to its respective target junction resistance R_{target} using an adaptive tuning process (block 809). At the completion of the tuning process, it is assumed that each Josephson junction comprises junction resistance which is at the target junction resistance R_{target} or near the target junction resistance R_{target} within some specified threshold percentage of the target junction resistance

$${R}_{target} , i . e . , \frac{\vert {R}_{target} - {R}_{current} \vert}{{R}_{target}} \leq x ( e . g . , x = 0.003 ( or 0.3 \% ) ) .$$

With each Josephson junction having a junction resistance which is at or near its target junction resistance R_{target}, it is assumed that each corresponding superconducting qubit has been tuned successfully and within a corresponding bound of precision to its respective target transition frequency.

In some embodiments, an adaptive tuning process (block 809) comprises an iterative laser tuning process for tuning the junction resistances of the Josephson junctions by implementing an asymptotic tuning methodology in which Josephson junctions of, e.g., qubits on a given multi-qubit device are adaptively and progressively tuned in an incremental manner to progressively shift junction resistances towards respective target junction resistances of the Josephson junctions. In some embodiments, adaptive and progressive tuning of a given Josephson junction is implemented by adaptively determining the anneal time (tₛₕₒₜ) for a given tuning iteration at a given laser power level based on a function of (i) an amount of resistance shift remaining (denoted ΔR_{remaining}) to reach the target junction resistance, and (ii) a total amount of anneal time spent for previous laser anneal iterations applied to the superconducting tunnel.

For example, an exemplary function for determining an anneal time (tₛₕₒₜ) for a given “shot” at a given laser power level is expressed as:

$${t}_{shot} ( {N}_{A} ) = \frac{Δ {R}_{target} - Δ R}{Δ {R}_{target}} \cdot {\sum }_{i = 1}^{{N}_{A} - 1} {t}_{shot} ( i ) for [ {N}_{A} > 1 ] ,$$

where N_{A} denotes an anneal number (or “shot” number), where ΔR_{target} denotes a difference between a target junction resistance (R_{target}) of a given Josephson junction and an initial measured resistance (denoted Rᵢₙᵢₜᵢₐₗ) of the given Josephson junction before the initial anneal operation (at N_{A}=0), and where ΔR denotes a difference between Rᵢₙᵢₜᵢₐₗ and a currently measured junction resistance (denoted R_{current}) of the given Josephson junction, which is measured in a given iteration before applying the next “shot” based on the computed anneal time tₛₕₒₜ for the given iteration. In other words, ΔR_{target}=R_{target}−Rᵢₙᵢₜᵢₐₗ. ΔR=R_{current}−Rᵢₙᵢₜᵢₐₗ, and ΔR_{remaining}=R_{target}−R_{current}. In the context of an adaptive tuning process, the parameter R_{current} denotes a current junction resistance that is measured at the beginning of each successive iteration of the adaptive tuning process, and the computation tₛₕₒₜ is performed for each successive iteration of the adaptive tuning process to determine a target anneal time for performing the laser anneal operation for given iteration. As noted above, the laser power level that is used in each iteration is the laser power level that was initially selected to perform the initial laser annealing operation (block 806, FIG. 8).

In the exemplary function for computing

$${t}_{shot} , the ratio \frac{Δ {R}_{target} - Δ R}{Δ {R}_{target}} = \frac{Δ {R}_{remaining}}{Δ {R}_{target}}$$

provides a weight factor that represents a percentage of the amount of a remaining amount of resistance shift needed to reach the target junction resistance R_{target} of the given Josephson junction based on the total resistance shift needed to reach the target junction resistance R_{target} starting from the initial measured junction resistance Rᵢₙᵢₜᵢₐₗ of the given Josephson junction. In addition, the summation Σᵢ₌₁^{N}^{_{A}}⁻¹ tₛₕₒₜ(i) provides weight factor based on the sum total time of all anneal times (total amount of all determined tₛₕₒₜ times) of all previous “shots” applied to the given Josephson junction. It is to be noted that the exemplary function for tₛₕₒₜ provides a linear combination of weight factors based on a product of ΔR_{remaining} and the total historical anneal time. In other embodiments, a function for computing tₛₕₒₜ can be based on other parameters and/or based on a non-linear function of the parameters ΔR_{remaining} and the total historical anneal time and/or other parameters, depending on, e.g., the application and/or the tuning characteristics of the Josephson junction as determined based on the associated tuning calibration data obtained using the calibration techniques as discussed herein.

Based the exemplary parameters of the function tₛₕₒₜ, at a given iteration of the tuning process, if the measured junction resistance indicates that there is a relatively large amount of resistance shift still needed to reach the target junction resistance R_{target}, the determined anneal time, tₛₕₒₜ, will be weighted (by the ratio

$$\frac{Δ {R}_{remaining}}{Δ {R}_{target}} )$$

to be longer. On the other hand, if there is a relatively small amount of resistance shift needed to reach the target junction resistance R_{target}, the anneal time, tₛₕₒₜ, will be weighted (by the ratio

$$\frac{Δ {R}_{remaining}}{Δ {R}_{target}} )$$

to be shorter. As another example, if the summation Σᵢ₌₁^{N}^{_{A}}⁻¹ tₛₕₒₜ(i) at a given iteration (e.g., at a given N_{A}) of the tuning process indicates a relatively large total amount of annealing has been performed on the given Josephson junction, this provides an indication that the given Josephson junction is tuning slowly, so that the next anneal time, tₛₕₒₜ, will be weighted (by the sum total anneal time) to be relatively long. On the other hand, if the summation Σᵢ₌₁^{N}^{_{A}}⁻¹ tₛₕₒₜ(i) at a given iteration of the tuning process indicates a relatively small total duration of annealing has been performed on the given Josephson junction, this provides an indication that the given Josephson junction is tuning relatively fast, so that the next anneal time, tₛₕₒₜ, will be weighted (by the sum total anneal time) to be relatively short.

The exemplary laser tuning methods as discussed herein are contrasted with conventional tuning method in which Josephson junctions are tuned to a target junction resistance using a single laser shot, which is unpredictable. The exemplary junction tuning techniques as disclosed herein are configured to perform an initial “shot” on a given Josephson junction to shift the junction resistance from the initial resistance (Rᵢₙᵢₜᵢₐₗ) to a junction resistance that is, e.g., about 50% to the target junction resistance (R_{target}), following by iteratively tuning the junction resistance of the given Josephson junction using multiple shots with anneal times that are adaptively determined for each shot to ensure a gradual approach to a target junction resistance, while accounting for relaxation of the junction resistances after laser annealing, which may require a period of time delay to settle closer to their final values. In an exemplary embodiment of a laser tuning progression after the first shot, the junctions (starting from the first, and progressing to the last) are each shot once in succession, and the process repeats starting at the first junction again. In this manner, the first junction resistance has time to relax and stabilize close to its final value prior to the subsequent shots. In another embodiment of a laser tuning progression after the first shot, each junction may be iteratively annealed to completion prior to annealing the next junction. In this case, a time delay may be implemented in between successive anneal iterations on the same junction, to allow the junction resistances to relax and stabilize near their final values to improve the accuracy of approaching resistance targets.

FIG. 9 schematically illustrates a process for aligning contact probes and laser spots to a Josephson junction of quantum bit, according to an exemplary embodiment of the disclosure. In some embodiments, FIG. 9 schematically illustrates the process steps that are implemented in blocks 803 and 805 of the tuning process 800 of FIG. 8. In particular, FIG. 9 schematically illustrates an exemplary FOV 930 which schematically illustrates a superconducting qubit 940. The superconducting qubit 940 comprises a transmon qubit comprising a capacitor and Josephson junction connected in parallel. In particular, the superconducting qubit 940 comprises a first superconducting pad 941, a second superconducting pad 942, and a Josephson junction 943 coupled to, and disposed between, the first and second superconducting pads 941 and 942. The first and second superconducting pads 941 and 942 comprise electrodes of a coplanar parallel-plate capacitor structure of the superconducting qubit 940. The Josephson junction 943 functions as a non-linear inductor which, when shunted with the capacitor formed by the first and second superconducting pads 941 and 942 forms an anharmonic LC oscillator with individually addressable energy levels (e.g., two lowest energy level corresponding to the ground state |0 [symbol] and the first excited state |1 [symbol] ) with a given transition frequency f₀₁. As noted above, laser annealing is applied to the Josephson junction 943 to monotonically increase the junction resistance the Josephson junction 943 to a target junction resistance, which results in an incremental decrease in transition frequency f₀₁ of the superconducting qubit 940 to a target transition frequency.

The FOV 930 represents the area of the object that is imaged by the microscope unit 130, wherein the size of the FOV is generally determined by the magnification of the objective lens 137. In the exemplary camera-objective architecture of the microscope unit 130, the FOV of the objective lens is applied to an image sensor (e.g., focal plane array) of the camera 132. Since the image sensor is rectangular in shape, the images captured by the microscope unit 130 have a rectangular FOV, as shown in FIG. 9, which does not capture the full circular FOV from the objective lens 137.

FIG. 9 schematically illustrates an exemplary alignment process in which a plurality of electrical probes 950-1 and 950-2 (e.g., probe tips) are aligned in contact with the first and second superconducting pads 941 and 942 which comprise the electrodes of a coplanar parallel-plate capacitor of the superconducting qubit 940. In particular, FIG. 9 illustrates an electrical probe configuration to implement a 4-wire (Kelvin) resistance measurement, wherein the electrical probes 950-1 comprise two probes that make contact to the first superconducting pad 941, and wherein the electrical probes 950-2 comprise two probes that make contact to the second superconducting pad 942. In this embodiment, the first and second superconducting pads 941 and 942 serve as the contact pads of the Josephson junction 943 on which the electrical probes are landed to perform an in-situ junction resistance measurement.

In some embodiments, a template image that is used to perform a pattern recognition alignment process comprises an image of the entirety of the superconducting qubit 940 including first and second superconducting pads 941 and 942, and the Josephson junction 943. In other embodiments, a template image that is used to perform a pattern recognition alignment process comprises an image of the Josephson junction 943. In other embodiments, one or more additional features of the template image can be used to perform a pattern recognition alignment process.

FIG. 9 further illustrates an exemplary pattern of laser spots 960 which can be used to laser anneal the Josephson junction 943. In particular, the exemplary pattern of laser spots 960 comprises 4 spots which correspond to, e.g., four laser beams generated by the laser beam shaper 135 (FIG. 1) implemented using a 2-by-2 diffractive beam splitter generate 4 laser beams that are projected onto the surface of the quantum chip 160 via the microscope unit 130. As schematically illustrated in FIG. 9, the Josephson junction 943 is aligned in the FOV 930 such that the laser beam spot pattern comprises two laser spots positioned on one side (e.g., above) of the Josephson junction 943, and two laser spots position on an opposite side (e.g., below) the Josephson junction 943, wherein the laser spots 960 are positioned to illuminate (and heat) regions of the upper surface of the quantum chip 160 in proximity to the Josephson junction 943, but not directly illuminate the Josephson junction 943. In other embodiments, other types of laser spot patterns can be utilized to laser anneal the Josephson junction 943. For example, the different laser spot patterns include, e.g., a 1-spot pattern, a 2-spot pattern, a 6-spot pattern, etc., depending on the application and/or the geometry of the features that are being laser annealed.

It is to be noted that while FIG. 9 illustrates a superconducting qubit 940 comprising a single Josephson junction 943, other types of superconducting qubits or quantum devices can have multiple Josephson junctions, which can be laser annealed concurrently using a suitable laser spot pattern. For example, some quantum devices, such as tunable qubit couplers, comprise a SQUID, wherein the SQUID comprises a pair of Josephson junctions which are connected in parallel to form a superconducting loop (referred to as SQUID loop) through which an external magnetic flux ϕ can be threaded to control operation of the tunable qubit coupler. In this regard, the Josephson junctions of a SQUID can be laser annealed and tuned concurrently by using a suitable laser spot pattern that is configured to heat the substrate regions surrounding the two Josephson junctions of the SQUID.

In other embodiments, a fractional tuning for the first laser annealing operation (initial shot) or any “shot” in the iterative tuning process, can be determined using probability distributions of resistance shift to minimize tuning time and/or minimize possibility of overshoot. For example, the exemplary process of FIG. 6A and FIG. 7 describes an embodiment for determining and utilizing a target combination of laser power and anneal time to perform an initial laser anneal operation on a given Josephson junction to achieve an initial junction resistance shift ΔRᵢₙᵢₜᵢₐₗ=R_{initial_target}−Rᵢₙᵢₜᵢₐₗ that is about 50% of the resistance shift to reach the target junction resistance R_{target} of the given Josephson junction. However, there exists some random variation to the amount by which a given “shot” will shift the junction resistance. For example, a given “shot” that is expected to provide a ΔRᵢₙᵢₜᵢₐₗ that reaches 50% to R_{target} may actually result in, e.g., a 47% or a 59% shift. Such variation can be accounted for using the exemplary calibration techniques as discussed herein, along with other statistical methods. For example, if the calibration process indicates a large variability of the initial junction resistance shift, the ΔR % which was initially selected to be 50% may be selected to be less, such that the risk of overshooting the target resistance is significantly mitigated.

For the calibration curves and parameters as shown in FIG. 3, the error bars (e.g., 332) provide means for computing other statistical parameters (e.g., median, median absolute deviation) and constructing a corresponding map of statistical variation. The first map can represent the median ΔR to be expected as a function of anneal power and anneal time. The second, or corresponding map, represents the statistical variation to be expected as a function of anneal power and anneal time. Variation is characterized by an error bar, standard deviation, statistical distribution or other well-known methods of statistics and probability.

In some embodiments, a map of statistical variation is generated using an exemplary process, as follows. When performing a calibration process such as shown in FIG. 4A, the same combination of laser power and anneal time is used to perform laser anneal operation on each of multiple identical Josephson junctions (e.g., 7 measurements on 7 Josephson junctions). From the several measured values of ΔR, the process determines a median and statistical variation for that particular laser power and anneal time, in terms of, e.g., standard deviation, histogram, statistical distribution, or other well-known statistical methods. Alternatively, when calibration data of ΔR at various laser powers and anneal times is fit to find a tuning curve (as in FIG. 5), the curve-fitting process can estimate the statistical variation of ΔR as a function of laser power and anneal time, in terms of a goodness-of-fit parameter or confidence interval. In some embodiments, a single calibration value of ΔR at a particular laser power and anneal time may be used to estimate both the median and statistical variation of ΔR at that power and time. For instance, some well-known statistical distributions such as the Poisson distribution have a statistical variance equal to the mean of the distribution.

The median and variation in ΔR parameters are then used as follows. Before a given “shot”, the process determines what likelihood of overshoot is acceptable. For example, the process may be configured to determine that an acceptable likelihood of overshoot is no more than 0.1% chance of overshooting the target resistance. The calibration process then choses the combination of laser power and anneal time exposure time, such that the median and statistical variation permit no more than 0.1% chance of overshooting the target resistance. For example, if the statistical distribution is a Gaussian (or Normal) distribution, then the initial resistance of the Josephson junction, plus the ΔR of that shot (as known from the median ΔR calibration map), plus three standard-deviations of ΔR (as known from the statistical-variation calibration map) must be less than the final target junction resistance. Alternatively, if, for example, the calibration process is configured to accept no more than 2% chance of overshoot, then the criterion changes to two standard-deviations of ΔR, etc.

In most cases, an initial shot to reach a 50% resistance shift to the target junction resistance will satisfy any reasonable requirement for chance of overshoot. Alternatively, the process can be configured to choose a maximum number of allowable times to “shoot” a given Josephson junction. This also represents a maximum amount of time for the tuning. For instance, if a given Josephson junction is to be “shot” no more than one time, then the initial junction resistance of the given Josephson junction plus the ΔR achieved for the “shot” should equal the final target junction resistance, i.e., an initial shot of 100% shift in resistance to the target junction resistance. However, in such a case, a 50% likelihood of overshoot can be expected, which may not be desirable for certain applications.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

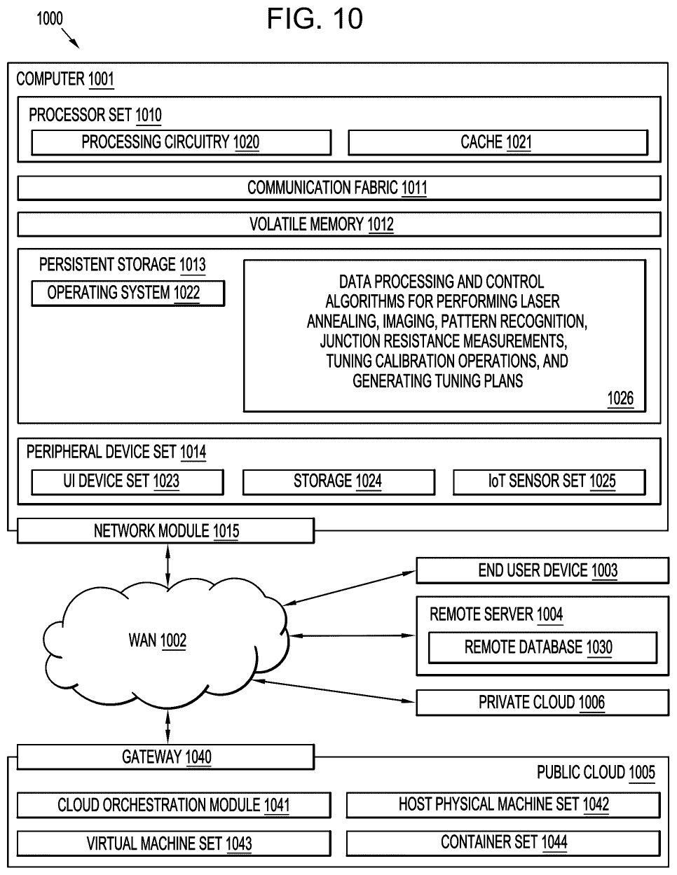

Computing environment 1000 of FIG. 10 contains an example of an environment for the execution of at least some of the computer code (block 1026) comprising data processing and control algorithms for performing various operations such as laser annealing operations, imaging operations, machine learning pattern recognition operations, junction resistance measurement operations, tunning calibration operations, generating tuning plans (e.g., frequency tuning plans) and other computer automated control and data processing operations as discussed herein for performing the exemplary methods shown or otherwise explained in conjunction with, e.g., FIGS. 1, 2, 3, 4A, 4B, 5, 6A-6D, 7, 8 and 9. In addition to block 1026, computing environment 1000 includes, for example, computer 1001, wide area network (WAN) 1002, end user device (EUD) 1003, remote server 1004, public cloud 1005, and private cloud 1006. In this embodiment, computer 1001 includes processor set 1010 (including processing circuitry 1020 and cache 1021), communication fabric 1011, volatile memory 1012, persistent storage 1013 (including operating system 1022 and block 1026, as identified above), peripheral device set 1014 (including user interface (UI), device set 1023, storage 1024, and Internet of Things (IoT) sensor set 1025), and network module 1015. Remote server 1004 includes remote database 1030. Public cloud 1005 includes gateway 1040, cloud orchestration module 1041, host physical machine set 1042, virtual machine set 1043, and container set 1044.

Computer 1001 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1030. As is well understood in the art of computer technology, and depending upon the technology, performance of a computer-implemented method may be distributed among multiple computers and/or between multiple locations. On the other hand, in this presentation of computing environment 1000, detailed discussion is focused on a single computer, specifically computer 1001, to keep the presentation as simple as possible. Computer 1001 may be located in a cloud, even though it is not shown in a cloud in FIG. 10. On the other hand, computer 1001 is not required to be in a cloud except to any extent as may be affirmatively indicated.

Processor set 1010 includes one, or more, computer processors of any type now known or to be developed in the future. Processing circuitry 1020 may be distributed over multiple packages, for example, multiple, coordinated integrated circuit chips. Processing circuitry 1020 may implement multiple processor threads and/or multiple processor cores. Cache 1021 is memory that is located in the processor chip package(s) and is typically used for data or code that should be available for rapid access by the threads or cores running on processor set 1010. Cache memories are typically organized into multiple levels depending upon relative proximity to the processing circuitry. Alternatively, some, or all, of the cache for the processor set may be located “off chip.” In some computing environments, processor set 1010 may be designed for working with qubits and performing quantum computing.

Computer readable program instructions are typically loaded onto computer 1001 to cause a series of operational steps to be performed by processor set 1010 of computer 1001 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1021 and the other storage media discussed below. The program instructions, and associated data, are accessed by processor set 1010 to control and direct performance of the inventive methods. In computing environment 1000, at least some of the instructions for performing the inventive methods may be stored in block 1026 in persistent storage 1013.

Communication fabric 1011 comprises the signal conduction paths that allow the various components of computer 1001 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1012 is any type of volatile memory now known or to be developed in the future. Examples include dynamic type random access memory (RAM) or static type RAM. Typically, the volatile memory is characterized by random access, but this is not required unless affirmatively indicated. In computer 1001, the volatile memory 1012 is located in a single package and is internal to computer 1001, but, alternatively or additionally, the volatile memory may be distributed over multiple packages and/or located externally with respect to computer 1001.

Persistent storage 1013 is any form of non-volatile storage for computers that is now known or to be developed in the future. The non-volatility of this storage means that the stored data is maintained regardless of whether power is being supplied to computer 1001 and/or directly to persistent storage 1013. Persistent storage 1013 may be a read only memory (ROM), but typically at least a portion of the persistent storage allows writing of data, deletion of data and re-writing of data. Some familiar forms of persistent storage include magnetic disks and solid-state storage devices. Operating system 1022 may take several forms, such as various known proprietary operating systems or open source Portable Operating System Interface type operating systems that employ a kernel. The code included in block 1026 typically includes at least some of the computer code involved in performing the inventive methods.

Peripheral device set 1014 includes the set of peripheral devices of computer 1001. Data communication connections between the peripheral devices and the other components of computer 1001 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1023 may include components such as a display screen, speaker, microphone, wearable devices (such as goggles and smart watches), keyboard, mouse, printer, touchpad, game controllers, and haptic devices. Storage 1024 is external storage, such as an external hard drive, or insertable storage, such as an SD card. Storage 1024 may be persistent and/or volatile. In some embodiments, storage 1024 may take the form of a quantum computing storage device for storing data in the form of qubits. In embodiments where computer 1001 is required to have a large amount of storage (for example, where computer 1001 locally stores and manages a large database) then this storage may be provided by peripheral storage devices designed for storing very large amounts of data, such as a storage area network (SAN) that is shared by multiple, geographically distributed computers. IoT sensor set 1025 is made up of sensors that can be used in Internet of Things applications. For example, one sensor may be a thermometer and another sensor may be a motion detector.

Network module 1015 is the collection of computer software, hardware, and firmware that allows computer 1001 to communicate with other computers through WAN 1002. Network module 1015 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1015 are performed on the same physical hardware device. In other embodiments (for example, embodiments that utilize software-defined networking (SDN)), the control functions and the forwarding functions of network module 1015 are performed on physically separate devices, such that the control functions manage several different network hardware devices. Computer readable program instructions for performing the exemplary inventive methods can typically be downloaded to computer 1001 from an external computer or external storage device through a network adapter card or network interface included in network module 1015.

WAN 1002 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1003 is any computer system that is used and controlled by an end user (for example, a customer of an enterprise that operates computer 1001), and may take any of the forms discussed above in connection with computer 1001. EUD 1003 typically receives helpful and useful data from the operations of computer 1001. For example, in a hypothetical case where computer 1001 is designed to provide a recommendation to an end user, this recommendation would typically be communicated from network module 1015 of computer 1001 through WAN 1002 to EUD 1003. In this way, EUD 1003 can display, or otherwise present, the recommendation to an end user. In some embodiments, EUD 1003 may be a client device, such as thin client, heavy client, mainframe computer, desktop computer and so on.

Remote server 1004 is any computer system that serves at least some data and/or functionality to computer 1001. Remote server 1004 may be controlled and used by the same entity that operates computer 1001. Remote server 1004 represents the machine(s) that collect and store helpful and useful data for use by other computers, such as computer 1001. For example, in a hypothetical case where computer 1001 is designed and programmed to provide a recommendation based on historical data, then this historical data may be provided to computer 1001 from remote database 1030 of remote server 1004.

Public cloud 1005 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1005 is performed by the computer hardware and/or software of cloud orchestration module 1041. The computing resources provided by public cloud 1005 are typically implemented by virtual computing environments that run on various computers making up the computers of host physical machine set 1042, which is the universe of physical computers in and/or available to public cloud 1005. The virtual computing environments (VCEs) typically take the form of virtual machines from virtual machine set 1043 and/or containers from container set 1044. It is understood that these VCEs may be stored as images and may be transferred among and between the various physical machine hosts, either as images or after instantiation of the VCE. Cloud orchestration module 1041 manages the transfer and storage of images, deploys new instantiations of VCEs and manages active instantiations of VCE deployments. Gateway 1040 is the collection of computer software, hardware, and firmware that allows public cloud 1005 to communicate through WAN 1002.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1006 is similar to public cloud 1005, except that the computing resources are only available for use by a single enterprise. While private cloud 1006 is depicted as being in communication with WAN 1002, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1005 and private cloud 1006 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
performing a calibration process which comprises:
performing laser annealing operations on a set of test superconducting tunnel junction devices using different combinations of laser power and anneal time;
determining junction resistance shifts of the test superconducting tunnel junction devices as a result of the laser annealing operations; and
utilizing the determined junction resistance shifts of the test superconducting tunnel junction to determine calibration data for configuring laser annealing operations for laser tuning superconducting tunnel junction devices corresponding to the test superconducting tunnel junction devices.

2. The method of claim 1, wherein utilizing the determined junction resistance shifts of the test superconducting tunnel junction devices to determine calibration data, comprises utilizing the determined junction resistance shifts to determine a maximum tuning range for each different combination of laser power and anneal time.

3. The method of claim 1, wherein utilizing the determined junction resistance shifts of the test superconducting tunnel junction to determine calibration data, comprises utilizing the determined junction resistance shifts to generate tuning curves that represent tuning rates for the different combinations of laser power and anneal time.

4. The method of claim 3, wherein each tuning curve corresponds to at least one of:
a different laser power setting, wherein each calibration tuning curve provides information regarding a percentage of junction resistance shift as a function of anneal time for the different laser power settings; and
a different percentage of junction resistance shift, wherein each calibration tuning curve provides information regarding anneal time as a function of laser power for the different percentages of junction resistance shift.

5. The method of claim 1, wherein determining junction resistance shifts of the test superconducting tunnel junction devices as a result of the laser annealing operations comprises:
for each test superconducting tunnel junction device, determining an initial junction resistance of the test superconducting tunnel junction device, prior to laser annealing the test superconducting tunnel junction device;
for each test superconducting tunnel junction device, determining a current junction resistance of the test superconducting tunnel junction device, subsequent to laser annealing the test superconducting tunnel junction device; and
for each test superconducting tunnel junction device, determining a junction resistance shift as a difference between of the measured current target junction resistance and the measured initial junction resistance of the test superconducting tunnel junction device.

6. The method of claim 1, wherein performing laser annealing operations on the set of test superconducting tunnel junction devices using multiple combinations of laser power and anneal time, comprises:
partitioning the set of test superconducting tunnel junction devices into multiple groups of test superconducting tunnel junction devices; and
for each group of test superconducting tunnel junction devices, performing laser annealing operations on the superconducting tunnel junction device in the group using a given combination of laser power and anneal time, which is selected among the different combinations of laser power and anneal time;
wherein each group of test superconducting tunnel junction devices is laser annealed using respective one of the different combinations of laser power and anneal time.

7. The method of claim 6, wherein utilizing the determined junction resistance shifts of the test superconducting tunnel junction to determine calibration data comprises:
for each group of test superconducting tunnel junction devices, computing one or more statistical parameters associated with the junction resistance shifts of the test superconducting tunnel junction that result from laser annealing each of the test superconducting tunnel junction devices in the group using the given combination of laser power and anneal time selected for the group; and
utilizing the statistical parameters to generate the calibration data.

8. The method of claim 1, wherein the set of test superconducting tunnel junction devices reside on one of:
a test quantum chip having the test superconducting tunnel junction devices which are fabricated using fabrication processes which are the same fabrication processes used to fabricate a plurality of superconducting tunnel junction devices that are to be laser tuned by laser annealing operations configured using the calibration data;
a quantum chip having the test superconducting tunnel junction devices and a plurality of superconducting tunnel junction devices that are to be laser tuned by laser annealing operations configured using the calibration data.

9. A method, comprising performing a laser annealing process to tune a plurality of superconducting tunnel junction devices on a quantum chip, wherein performing the laser annealing process comprises configuring a laser annealing process to laser tune a given superconducting tunnel junction device using tuning calibration data obtained by laser annealing operations performed on a set of test superconducting tunnel junction devices using different combinations of laser power and anneal time, the test superconducting tunnel junction devices corresponding to the given superconducting tunnel junction device.

10. The method of claim 9, wherein configuring the laser annealing process to laser tune the given superconducting tunnel junction device, comprises:
determining an initial junction resistance of the given superconducting tunnel junction device, prior to laser annealing the given superconducting tunnel junction device; and
utilizing the calibration data to determine a combination of laser power and anneal time for laser annealing the given superconducting tunnel junction device to shift the junction resistance of the given superconducting tunnel junction device by an initial tuning threshold amount to a target junction resistance of the given superconducting tunnel junction device.

11. The method of claim 9, wherein the initial tuning threshold amount is in a range of about 40% to about 60% of a difference between the target junction resistance and the initial junction resistance.

12. The method of claim 9, wherein:
the plurality of superconducting tunnel junction devices on the quantum chip comprises Josephson junctions of superconducting quantum bits in lattice on the quantum chip; and
the laser annealing process is configured to laser tune junction resistances of the Josephson junctions to tune respective transition frequencies of the superconducting quantum bits based on a frequency tuning plan that is generated at least in part on tuning constraints obtained from the tuning calibration data.

13. A system, comprising:
a laser annealing apparatus; and
a control system operatively coupled to the laser annealing apparatus;
wherein the laser annealing apparatus is controlled by the control system to perform a calibration process, wherein the control process is configured to:
perform laser annealing operations on a set of test superconducting tunnel junction devices on a quantum chip, using different combinations of laser power and anneal time;
determine junction resistance shifts of the test superconducting tunnel junction devices as a result of the laser annealing operations; and
utilize the determined junction resistance shifts of the test superconducting tunnel junction to determine calibration data for configuring laser annealing operations for laser tuning superconducting tunnel junction devices corresponding to the superconducting tunnel junction devices.

14. The system of claim 13, wherein in utilizing the utilizing the determined junction resistance shifts of the test superconducting tunnel junction to determine calibration data, the control system is configured to:
utilize the determined junction resistance shifts to determine a maximum tuning range for each different combination of laser power and anneal time; and
utilize the determined junction resistance shifts to generate tuning curves that represent tuning rates for the different combinations of laser power and anneal time.

15. The system of claim 14, wherein each tuning curve corresponds to at least one of:
a different laser power setting, wherein each calibration tuning curve provides information regarding a percentage of junction resistance shift as a function of anneal time for the different laser power settings; and
a different percentage of junction resistance shift, wherein each calibration tuning curve provides information regarding anneal time as a function of laser power for the different percentages of junction resistance shift.

16. The system of claim 14, wherein in determining junction resistance shifts of the test superconducting tunnel junction devices as a result of the laser annealing operations, the control system is configured to:
for each test superconducting tunnel junction device, determine an initial junction resistance of the test superconducting tunnel junction device, prior to laser annealing the test superconducting tunnel junction device;
for each test superconducting tunnel junction device, determine a current junction resistance of the test superconducting tunnel junction device, subsequent to laser annealing the test superconducting tunnel junction device; and
for each test superconducting tunnel junction device, determine a junction resistance shift as a difference between of the measured current target junction resistance and the measured initial junction resistance of the test superconducting tunnel junction device.

17. The system of claim 13, wherein in performing laser annealing operations on the set of test superconducting tunnel junction devices using multiple combinations of laser power and anneal time, the control system is configured to:
partition the set of test superconducting tunnel junction devices into multiple groups of test superconducting tunnel junction devices; and
for each group of test superconducting tunnel junction devices, perform laser annealing operations on the superconducting tunnel junction device in the group using a given combination of laser power and anneal time, which is selected among the different combinations of laser power and anneal time;
wherein each group of test superconducting tunnel junction devices is laser annealed using respective one of the different combinations of laser power and anneal time.

18. The system of claim 13, wherein in utilizing the determined junction resistance shifts of the test superconducting tunnel junction to determine calibration data, the control system is configured to:
for each group of test superconducting tunnel junction devices, compute one or more statistical parameters associated with the junction resistance shifts of the test superconducting tunnel junction that result from laser annealing each of the test superconducting tunnel junction devices in the group using the given combination of laser power and anneal time selected for the group; and
utilize the statistical parameters to generate the calibration data.

19. The system of claim 13, wherein the quantum chip comprises one of:
a test quantum chip having the test superconducting tunnel junction devices which are fabricated using fabrication processes which are the same fabrication processes used to fabricate a plurality of superconducting tunnel junction devices that are to be laser tuned by laser annealing operations configured using the calibration data; and
a quantum chip having the test superconducting tunnel junction devices and a plurality of superconducting tunnel junction devices that are to be laser tuned by laser annealing operations configured using the calibration data.

20. A system comprising:
a laser annealing apparatus; and
a control system operatively coupled to the laser annealing apparatus;
wherein the laser annealing apparatus is controlled by the control system to perform laser tuning process wherein the control system is configured to perform a laser annealing operations to tune a plurality of superconducting tunnel junction devices on a quantum chip, wherein in performing the laser annealing operations, the control system configures a laser annealing operation to laser tune a given superconducting tunnel junction device using tuning calibration data obtained by laser annealing operations performed on a set of test superconducting tunnel junction devices using different combinations of laser power and anneal time, the test superconducting tunnel junction devices corresponding to the given superconducting tunnel junction device.

21. The system of claim 20, wherein in configuring the laser annealing operation to laser tune the given superconducting tunnel junction device, the control system is configured to:
determine an initial junction resistance of the given superconducting tunnel junction device, prior to laser annealing the given superconducting tunnel junction device; and
utilize the calibration data to determine a combination of laser power and anneal time for laser annealing the given superconducting tunnel junction device to shift the junction resistance of the given superconducting tunnel junction device by an initial tuning threshold amount to a target junction resistance of the given superconducting tunnel junction device.

22. The system of claim 21, wherein the initial tuning threshold amount is in a range of about 40% to about 60% of a difference between the target junction resistance and the initial junction resistance.

23. The system of claim 20, wherein:
the plurality of superconducting tunnel junction devices on the quantum chip comprises Josephson junctions of superconducting quantum bits in a lattice on the quantum chip; and
the control system configures the laser annealing process to laser tune junction resistances of the Josephson junctions to tune respective transition frequencies of the superconducting quantum bits based on a frequency tuning plan that is generated based at least in part on tuning constraints obtained from the tuning calibration data.

24. A computer program product for performing laser annealing, the computer program product comprising:
one or more computer readable storage media, and program instructions collectively stored on the one or more computer readable storage media, the program instructions comprising:
program instructions to perform laser annealing operations on a set of test superconducting tunnel junction devices using different combinations of laser power and anneal time;
program instruction to determine junction resistance shifts of the test superconducting tunnel junction devices as a result of the laser annealing operations; and
program instructions to utilize the determined junction resistance shifts of the test superconducting tunnel junction to determine calibration data for configuring laser annealing operations for laser tuning superconducting tunnel junction devices corresponding to the test superconducting tunnel junction devices.

25. The computer program product of claim 24, wherein the program instructions to utilize the determined junction resistance shifts of the test superconducting tunnel junction to determine calibration data, the control system, comprise:
program instructions to utilize the determined junction resistance shifts to determine a maximum tuning range for each different combination of laser power and anneal time; and
program instructions to utilize the determined junction resistance shifts to generate tuning curves that represent tuning rates for the different combinations of laser power and anneal time;
wherein each tuning curve corresponds to at least one of:
a different laser power setting, wherein each calibration tuning curve provides information regarding a percentage of junction resistance shift as a function of anneal time for the different laser power settings; and
a different percentage of junction resistance shift, wherein each calibration tuning curve provides information regarding anneal time as a function of laser power for the different percentages of junction resistance shift.
